(19) United States
(12) Patent Application Publication
(10) Pub. No.: US 2025/0169338 A1
(43) Pub. Date: May 22, 2025

(54) DISPLAY PANEL AND METHOD OF PREPARING THE SAME

(71) Applicants: HEFEI VISIONOX TECHNOLOGY CO., LTD., Hefei (CN); VISIONOX TECHNOLOGY INC., Suzhou (CN)

(72) Inventors: Yuting FU, Hefei (CN); Qing BAI, Hefei (CN); Xueijing ZHU, Hefei (CN); Yuan YAO, Hefei (CN); Xiaoxi SUN, Hefei (CN); Wei-JU HUANG, Hefei (CN); YI-YU LAI, Hefei (CN); Liping XU, Hefei (CN)

(73) Assignees: HEFEI VISIONOX TECHNOLOGY CO., LTD., Hefei (CN); VISIONOX TECHNOLOGY INC., Suzhou (CN)

(21) Appl. No.: 19/005,260

(22) Filed: Dec. 30, 2024

Related U.S. Application Data
(63) Continuation of application No. PCT/CN2024/111926, filed on Aug. 14, 2024.

(30) Foreign Application Priority Data
Nov. 16, 2023 (CN) 202311550470.0
Jan. 31, 2024 (CN) 202410141739.8
Feb. 18, 2024 (CN) 202410181878.3
Mar. 1, 2024 (CN) 202410239791.7

(51) Int. Cl. H10K 59/80; H10K 59/12; H10K 59/122

(52) U.S. Cl. CPC H10K 59/873; H10K 59/1201; H10K 59/122

(57) ABSTRACT

Provided are a display panel and a method of preparing the same. The display has a display region and a non-display region and includes a substrate and an encapsulation structure, a protective layer and multiple light-emitting devices which are located on the substrate. The multiple light-emitting devices are located in the display region. The encapsulation structure is located on a side of the light-emitting devices away from the substrate, and the encapsulation structure includes a first encapsulation layer and a second encapsulation layer located on a side of the first encapsulation layer facing away from the substrate, the first encapsulation layer and the second encapsulation layer cover the light-emitting devices, and the orthographic projection of the second encapsulation layer on the substrate is located in the display region and the non-display region.

### CROSS-REFERENCES TO RELATED APPLICATIONS

This is a continuation of International Patent Application No. PCT/CN2024/111926, filed on Aug. 14, 2024, which is based on and claims priority to Chinese Patent Application No. 202311550470.0 filed on Nov. 16, 2023, Chinese Patent Application No. 202410141739.8 filed on Jan. 31, 2024, Chinese Patent Application No. 202410181878.3 filed on Feb. 18, 2024, and Chinese Patent Application No. 202410239791.7 filed on Mar. 1, 2024, the disclosures of which are incorporated herein by reference in their entireties.

### TECHNICAL FIELD

The present disclosure relates to the field of display technology and, specifically, to a display panel and a method of preparing the same.

### BACKGROUND

An organic light-emitting diode (OLED) is a type of organic thin-film electroluminescent device. The OLED has attracted great attention and has been widely used in electronic display products because of its advantages such as simple preparation process, low cost, low power consumption, high brightness, wide viewing angle, high contrast ratio, and capability to achieve flexible display.

However, the existing electronic display products are limited to the structure design of the electronic display products, thereby making it difficult to further improve the yield of display panels.

### SUMMARY

A first aspect of the present disclosure provides a display panel. The display panel has a display region and a non-display region, and the display panel includes a substrate and an encapsulation structure, a protective layer and multiple light-emitting devices which are located on the substrate. The light-emitting devices are located in the display region. The encapsulation structure is located on a side of the light-emitting device away from the substrate, and the encapsulation structure includes a first encapsulation layer and a second encapsulation layer located on a side of the first encapsulation layer facing away from the substrate. The first encapsulation layer and the second encapsulation layer cover the light-emitting device. The orthographic projection of the second encapsulation layer on the substrate is located in the display region and the non-display region. The protective layer is at least partially located in the non-display region and located on a side of the second encapsulation layer facing the substrate. The protective layer is in direct contact with the second encapsulation layer in the non-display region. The protective layer and the second encapsulation layer are of the same material type.

In the above solution, the protective layer can protect the underlying structures during the preparation process of the first encapsulation layer to avoid damage to the substrate or the structures between the substrate and the protective layer, thereby ensuring the quality of the display panel.

In a specific embodiment of the first aspect of the present disclosure, the display panel further includes a pixel defining layer located on the substrate. The pixel defining layer is located in the display region and is provided with multiple pixel openings. The pixel openings are used for accommodating light-emitting devices. The protective layer includes a first sub-protective layer. The first sub-protective layer laps the pixel defining layer. The first sub-protective layer and the second encapsulation layer are in direct contact in the non-display region.

In the above solution, by lapping the first sub-protective layer and the pixel defining layer, the existence of a gap between the first sub-protective layer and the pixel defining layer is avoided, thereby improving the protective effect on the underlying structures during the preparation process of the first encapsulation layer.

In a specific embodiment of the first aspect of the present disclosure, the pixel defining layer, the first encapsulation layer, the second encapsulation layer, and the protective layer are inorganic film layers. The inorganic film layer has a high density and thus has a stronger blocking effect on etching, thereby improving the protective effect on the underlying structures.

Optionally, the material of the pixel defining layer, the first encapsulation layer, the second encapsulation layer, and the protective layer includes one of silicon oxide, silicon nitride or silicon oxynitride.

In a specific embodiment of the first aspect of the present disclosure, the first sub-protective layer and the pixel defining layer are disposed in the same layer and of the same material. In this manner, the first sub-protective layer can be synchronously prepared during the preparation of the pixel defining layer, thereby simplifying the preparation process of the display panel.

Optionally, in the case where the first sub-protective layer and the pixel defining layer are disposed in the same layer and of the same material, the orthographic projection of the first sub-protective layer on the substrate is located in the non-display region.

In a specific embodiment of the first aspect of the present disclosure, the layer in which the first sub-protective layer is located is located on a side, facing the substrate, of the layer in which the pixel defining layer is located. For example, the orthographic projection of the first sub-protective layer on the substrate is located in the display region and the non-display region, the first sub-protective layer at least partially overlaps the pixel defining layer in the display region, and the first sub-protective layer is located between the pixel defining layer and the substrate.

In the above solution, in the process of forming the pixel defining layer, the first sub-protective layer formed before the pixel defining layer can protect the underlying structures, thereby ensuring the quality of the display panel.

Optionally, in the case where the layer in which the first sub-protective layer is located is located on a side, facing the substrate, of the layer in which the pixel defining layer is located, the orthographic projection of the pixel defining layer on the substrate is located within the orthographic projection of the first sub-protective layer on the substrate. In this manner, the first sub-protective layer covers the entire display region, thereby protecting the structures under the pixel defining layer in the display region during the formation of the pixel defining layer.

In a specific embodiment of the first aspect of the present disclosure, in the case where the layer in which the first sub-protective layer is located is located on a side, facing the substrate, of the layer in which the pixel defining layer is located, the light-emitting device includes a first electrode, a light-emitting function layer, and a second electrode which are sequentially stacked on the substrate, and the first sub-protective layer is located between the first electrode and the substrate. In this manner, the setting of the first sub-protective layer does not affect the manners of setting and forming the first electrode. Furthermore, the bonding strength between the first electrode and the substrate (through the first sub-protective layer) can be strengthened, thereby reducing the risk of the first electrode being detached.

In a specific embodiment of the first aspect of the present disclosure, in the case where the layer in which the first sub-protective layer is located is located on a side, facing the substrate, of the layer in which the pixel defining layer is located, the display panel further includes a first planarization layer located between the substrate and the first electrode. The first planarization layer is located in the display region and the non-display region, and the first planarization layer is in contact with the first sub-protective layer in the non-display region. The first sub-protective layer is located between the first electrode and the first planarization layer in the display region.

In the above solution, the first sub-protective layer can protect the first planarization layer during the preparation process of the first encapsulation layer to prevent the first planarization layer from being damaged, thereby ensuring the quality of the display panel.

Optionally, in the case where the layer in which the first sub-protective layer is located is located on a side, facing the substrate, of the layer in which the pixel defining layer is located, the display panel further includes a first common electrode line and a second common electrode line. The first common electrode line is located in the display region and the non-display region. The second common electrode line is located in the non-display region. The first common electrode line is located on a side, facing away from the substrate, of the first sub-protective layer and on a side, facing away from the substrate, of the pixel defining layer. The second common electrode line is located between the first sub-protective layer and the substrate. The first common electrode line is electrically connected to the second electrode. In the non-display region, the first sub-protective layer is provided with a first via, and the first planarization layer is provided with a second via that connected with the first via. The first common electrode line is connected to the second common electrode line through the first via and the second via.

In the above solution, the first common electrode line and the second common electrode line form a common electrode line, and the first sub-protective layer and the first planarization layer are provided with the first via and the second via respectively for connecting the first common electrode line and the second common electrode line to ensure that while the common electrode line is connected to the second electrode, the major portion (the second common electrode line) of the common electrode line in the non-display region can be covered by the first sub-protective layer and the first planarization layer, thereby reducing the risk of the common electrode line being damaged during the preparation process of the first encapsulation layer and the light-emitting device.

In a specific embodiment of the first aspect of the present disclosure, the layer in which the first sub-protective layer is located is located on a side, facing away from the substrate, of the layer in which the pixel defining layer is located. For example, the orthographic projection of the first sub-protective layer on the substrate is located in the display region and the non-display region, the first sub-protective layer at least partially overlaps the pixel defining layer in the display region, and the pixel defining layer is located between the first sub-protective layer and the substrate.

In the above solution, the first sub-protective layer covers the edge portion of the pixel defining layer to edge-wrap the pixel defining layer, thereby reducing the risk of the occurrence of cracks on the edges of the pixel defining layer.

In a specific embodiment of the first aspect of the present disclosure, in the case where the layer in which the first sub-protective layer is located is located on a side, facing away from the substrate, of the layer in which the pixel defining layer is located, the light-emitting device includes a first electrode, a light-emitting function layer, and a second electrode which are sequentially stacked on the substrate in a direction away from the substrate, and the orthographic projection of the first sub-protective layer on the substrate is located outside the orthographic projection of the first electrode on the substrate. In this manner, the setting of the first sub-protective layer does not affect the manners of setting and forming the first electrode, thereby ensuring the quality of the light-emitting device.

In a specific embodiment of the first aspect of the present disclosure, in the case where the layer in which the first sub-protective layer is located is located on a side, facing away from the substrate, of the layer in which the pixel defining layer is located, the display panel further includes a first planarization layer located between the substrate and the first electrode. The first planarization layer is located in the display region and the non-display region and is in contact with the first sub-protective layer in the non-display region.

Optionally, in the case where the layer in which the first sub-protective layer is located is located on a side, facing away from the substrate, of the layer in which the pixel defining layer is located, the display panel further includes a first common electrode line and a second common electrode line. The first common electrode line is located in the display region and the non-display region. The second common electrode line is located in the non-display region. The first common electrode line is located on a side, facing away from the substrate, of the first sub-protective layer and on a side, facing away from the substrate, of the pixel defining layer. The second common electrode line is located between the first sub-protective layer and the substrate. The first common electrode line is electrically connected to the second electrode. In the non-display region, the first sub-protective layer is provided with a first via, and the first planarization layer is provided with a second via connected with the first via. The first common electrode line and the second common electrode line are connected through the first via and the second via.

In a specific embodiment of the first aspect of the present disclosure, the display panel further includes at least one bank located in the non-display region. The bank surrounds at least a portion of the display region. The bank includes a top film layer on a side away from the substrate. The first sub-protective layer is in contact with the top film layer. The first sub-protective layer and the top film layer are of the same material.

In the above solution, the first sub-protective layer can protect the side surface of the bank during the preparation of the pixel defining layer, thereby reducing the risk of the bank being damaged by etching.

Optionally, the top film layer is an inorganic film layer. In this manner, in the case where the first sub-protective layer is an inorganic film layer, the top film layer and the first sub-protective layer can be bound to each other with a high bonding strength, thereby reducing the risk of the top film layer and the first sub-protective layer being detached from the substrate. Furthermore, the top film layer, which is an inorganic film layer, has a high degree of densification, thereby preventing water and oxygen from invading the interior of the bank.

In a specific embodiment of the first aspect of the present disclosure, the first sub-protective layer and the top film layer are arranged in the same layer, and the first sub-protective layer covers the side surface of the dank. In this manner, the top film layer can be synchronously prepared during the preparation of the first sub-protective layer, thereby simplifying the preparation process of the display panel.

In another specific embodiment of the first aspect of the present disclosure, the first sub-protective layer covers the top film layer, the first sub-protective layer is located on a side, facing away from the substrate, of the top film layer, and the orthographic projection of the top film layer on the substrate is located within the orthographic projection of the first sub-protective layer on the substrate. In this manner, the first sub-protective layer covers the top film layer to protect the top film layer during the preparation process of the pixel defining layer, thereby reducing the risk of the bank being damaged by etching.

In a specific embodiment of the first aspect of the present disclosure, the top film layer includes multiple first openings. The orthographic projection of the first sub-protective layer on the substrate is located outside the orthographic projection of the first opening on the substrate, and the orthographic projection of the first opening on the substrate is located within the orthographic projection of the second encapsulation layer on the substrate. The second encapsulation layer covers and fills the first openings.

In the above solution, the first openings may be used for releasing the gas enclosed inside the bank, thereby ensuring the encapsulation effect of the display panel. Furthermore, the second encapsulation layer covers and fills the first openings to seal the first openings, thereby preventing the gas from invading the bank or the residual gas in the bank from escaping during the subsequent preparation processes. In addition, with the setting of the first openings, the second encapsulation layer is embedded in the bank equivalently, thereby reducing the risk of the second encapsulation layer being detached from the substrate.

In a specific embodiment of the first aspect of the present disclosure, the bank includes a support layer. The support layer is located between the top film layer and the substrate, and the first sub-protective layer covers the side surface of the support layer. In this manner, the top film layer and the first sub-protective layer fully cover the support layer to protect the support layer.

Optionally, the support layer is an organic film layer. The organic film layer has a larger thickness, thereby enabling the height of the bank to be easily increased. Accordingly, although the organic film layer is also easily etched, in the case where the support layer is covered by the top film layer and the first sub-protective layer, the risk of the support layer being etched is reduced.

In a specific embodiment of the first aspect of the present disclosure, the display panel further includes a first planarization layer. The first planarization layer is located in the display region and the non-display region. The first planarization layer is located between the pixel defining layer and the substrate and between the first sub-protective layer and the substrate. At least a portion of the support layer and the first planarization layer are in the same layer, and the support layer and the first planarization layer are of the same material. The first planarization layer is spaced apart from the bank. In this manner, the support layer can be synchronously prepared during the preparation of the first planarization layer, thereby simplifying the preparation process of the display panel.

In a specific embodiment of the first aspect of the present disclosure, the display panel further includes a third encapsulation layer. The third encapsulation layer is located between the first encapsulation layer and the second encapsulation layer. The third encapsulation layer is located on a side of the bank facing the display region. The first sub-protective layer is in direct contact with the third encapsulation layer between the bank and the display region. Optionally, the third encapsulation layer is an organic film layer. The bank defines the distribution region of the third encapsulation layer, and the third encapsulation layer is sandwiched between the first sub-protective layer and the second encapsulation layer to protect the third encapsulation layer.

In a specific embodiment of the first aspect of the present disclosure, the protective layer further includes a second sub-protective layer. At least a portion of the second sub-protective layer is located in the non-display region. The second sub-protective layer is located between the first sub-protective layer and the substrate in the non-display region.

In a specific embodiment of the first aspect of the present disclosure, the display panel further includes a first planarization layer. The first planarization layer is located in the display region and the non-display region. The first planarization layer is located between the pixel defining layer and the substrate and between the first sub-protective layer and the substrate. The orthographic projection of the first planarization layer on the substrate is located within the orthographic projection of the first sub-protective layer on the substrate and within the orthographic projection of the second sub-protective layer on the substrate in the non-display region. The second sub-protective layer extends into the display region. The first sub-protective layer and the second sub-protective layer are spaced apart by the first planarization layer. In the above solution, the second sub-protective layer can protect the underlying structures. Furthermore, the protective layer is a structure including at least two film layers to further enhance the protective effect of the protective layer, thereby further improving the quality of the display panel.

Optionally, the orthographic projection of the pixel defining layer on the substrate is located within the orthographic projection of the second sub-protective layer on the substrate. In this manner, the second sub-protective layer covers the entire display region to protect the structures below the pixel defining layer in the display region during the preparation process of the pixel defining layer.

In a specific embodiment of the first aspect of the present disclosure, the display panel further includes a first signal line. The first signal line is located on a side of the first planarization layer facing the substrate. The presence of the first signal line requires the setting of other film layers to space the first signal line from the neighboring conductive structures, thereby providing an interlayer location for setting the second sub-protective layer.

In a specific embodiment of the first aspect of the present disclosure, the second sub-protective layer is located between the first signal line and the first planarization layer. The light-emitting device includes a first electrode, a light-emitting function layer, and a second electrode which are sequentially stacked on the substrate in the direction away from the substrate. The first sub-protective layer is located between the first electrode and the substrate. The display panel further includes a first common electrode line and a second common electrode line. The first common electrode line is located in the display region and the non-display region. The second common electrode line is located in the non-display region. The first common electrode line is located on a side of the first sub-protective layer facing away from the substrate and on a side of the pixel defining layer facing away from the substrate. The second common electrode line is located between the first sub-protective layer and the substrate. The first common electrode line is electrically connected to the second electrode. The first sub-protective layer and the second sub-protective layer are located between the first common electrode line and the second common electrode line in the non-display region.

In the above solution, the second sub-protective layer can protect the first signal line during the preparation of the first planarization layer (for example, during the etching process required for opening holes). Furthermore, the second sub-protective layer can prevent substances such as water and oxygen in the first planarization layer from invading the first signal line, thereby reducing the risk of the first signal line being corroded and damaged.

Optionally, in the case where the second sub-protective layer is located between the first signal line and the first planarization layer, in the non-display region, the first sub-protective layer is provided with a first via, the first planarization layer is provided with a second via connected with the first via, and the second sub-protective layer is provided with a third via connected with the second via. The first common electrode line is connected to the second common electrode line through the first via, the second via, and the third via.

Optionally, in the case where the second sub-protective layer is located between the first signal line and the first planarization layer, the second common electrode line and the first signal line are in the same layer and of the same material. In this manner, the first signal line can be synchronously prepared during the preparation of the second common electrode line, thereby simplifying the preparation process of the display panel.

Optionally, in the case where the second sub-protective layer is located between the first signal line and the first planarization layer, the first signal line includes at least one of a power supply line or a data line.

In a specific embodiment of the first aspect of the present disclosure, the display panel further includes a second signal line. The second signal line and the second sub-protective layer are located between the first signal line and the substrate. When the first signal line and the second signal line are located in different layers, the wiring space of the display panel can be increased, thereby reducing the wiring difficulty. Accordingly, the number of film layers to be set can also be increased, thereby providing more options for the interlayer location of the second sub-protective layer.

In a specific embodiment of the first aspect of the present disclosure, the display panel further includes a second planarization layer and a third planarization layer. The third planarization layer, the second signal line, the second planarization layer, the first signal line, and the first planarization layer are sequentially arranged in the direction away from the substrate. The second sub-protective layer is located between the second planarization layer and the second signal line or the second sub-protective layer is located between the second signal line and the third planarization layer.

In a specific embodiment of the first aspect of the present disclosure, the light-emitting device includes a first electrode, a light-emitting function layer, and a second electrode which are sequentially stacked on the substrate in the direction away from the substrate. The first sub-protective layer is located between the first electrode and the substrate. The display panel further includes a first common electrode line and a second common electrode line. The first common electrode line is located in the display region and the non-display region. The second common electrode line is located in the non-display region. The first common electrode line is located on a side, facing away from the substrate, of the first sub-protective layer and on a side, facing away from the substrate, of the pixel defining layer. The second common electrode line is located between the first sub-protective layer and the substrate. The first common electrode line is electrically connected to the second electrode. The display panel further includes at least one bank located in the non-display region. The bank surrounds the display region. The second common electrode line and the second sub-protective layer penetrate the interior of the bank.

In the above solution, at the location where the bank is located, the height at which the second common electrode line needs to be to cross the bank can be reduced, thereby reducing the risk of breakage of the second common electrode line. Furthermore, at this location, the second common electrode line is located inside the bank to allow the bank to protect the second common electrode line, thereby further reducing the risk of the second common electrode line being damaged by etching.

Optionally, the bank includes a top film layer and a support layer. The support layer is located between the top film layer and the substrate, and the portion where the second common electrode line and the second sub-protective layer penetrate the bank is located inside the support layer.

Optionally, the support layer includes a first sub-support layer and a second sub-support layer which are stacked on one another. The second sub-support layer is located between the first sub-support layer and the substrate. The first sub-support layer and the first planarization layer are in the same layer and of the same material. The second sub-support layer and at least one of the second planarization layer or the third planarization layer are in the same layer and of the same material. The portion where the second common electrode line and the second sub-protective layer penetrate the bank is located between the first sub-support layer and the second sub-support layer.

In this manner, the setting of the support layer does not increase the preparation process flow of the display panel.

In a specific embodiment of the first aspect of the present disclosure, the second sub-protective layer is located between the second signal line and the second planarization layer. In this manner, the second sub-protective layer can protect the second signal line during the preparation of the second planarization layer (for example, during the process of forming vias). Furthermore, the second sub-protective layer can prevent substances such as water and oxygen in the second planarization layer from invading the first signal line, thereby reducing the risk of the first signal line being corroded and damaged.

Optionally, in the case where the second sub-protective layer is located between the second signal line and the second planarization layer, the second common electrode line and the second signal line are in the same layer and of the same material, and the second sub-protective layer covers the second common electrode line. In this manner, the second common electrode line can be synchronously prepared during the preparation of the second signal line, thereby simplifying the preparation process of the display panel.

In a specific embodiment of the first aspect of the present disclosure, in the case where the second sub-protective layer is located between the second signal line and the second planarization layer, the first sub-support layer is provided with multiple second openings. The second openings are arranged at intervals along the bank. The second openings expose the second sub-protective layer. The top film layer includes first openings, and each of the first openings corresponds to a respective one of the second openings. The second encapsulation layer covers the second openings and the first openings and is in direct contact with the second sub-protective layer through the second openings and the first openings.

In the above solution, the second openings and the first openings can release the gas enclosed inside the first sub-support layer, thereby ensuring the encapsulation effect of the display panel. Furthermore, the second encapsulation layer covers and fills the second openings and the first openings to seal the second openings and the first openings, thereby preventing the gas from invading the bank or the residual gas in the bank from escaping during the subsequent preparation processes. In addition, with the setting of the second openings and the first openings, the second sub-protective layer can be in direct contact with the second encapsulation layer, and the second encapsulation layer is embedded in the bank equivalently, thereby reducing the risk of the second encapsulation layer being detached from the substrate.

In another specific embodiment of the first aspect of the present disclosure, the first sub-support layer is provided with multiple second openings. The second openings are arranged at intervals along the bank. The second openings expose the second sub-protective layer. The first sub-protective layer covers the top film layer and the second openings to be in direct contact with the second sub-protective layer through the second openings.

In the above solution, the second openings may be used for releasing the gas enclosed inside the first sub-support layer, thereby ensuring the encapsulation effect of the display panel. Furthermore, the first sub-protective layer covers and fills the second openings to seal the second openings, thereby preventing the gas from invading the bank or the residual gas in the bank from escaping during the subsequent preparation processes. In addition, with the setting of the second openings, the first sub-protective layer can be in direct contact with the second encapsulation layer, and the second encapsulation layer is embedded in the bank equivalently, thereby reducing the risk of the second encapsulation layer being detached from the substrate.

In another specific embodiment of the first aspect of the present disclosure, the second common electrode line includes at least one air permeable hole. The air permeable hole penetrates the second common electrode line. The air permeable hole may be used for releasing the gas enclosed inside the second sub-support layer, thereby ensuring the encapsulation effect of the display panel.

Optionally, multiple air permeable holes are provided and arranged at intervals along the bank.

In another specific embodiment of the first aspect of the present disclosure, the substrate includes a driving circuit layer. The driving circuit layer is located in the display region, and the third planarization layer planarizes the driving circuit layer.

In a specific embodiment of the first aspect of the present disclosure, the display panel further includes a first isolation structure located on a side of the pixel defining layer away from the substrate. The first isolation structure is located in the display region and is provided with multiple first isolation openings. The first isolation opening communicates with the pixel opening. The first encapsulation layer includes multiple encapsulation units. The encapsulation unit is located on a side of the light-emitting device facing away from the substrate. The light-emitting device includes a first electrode, a light-emitting function layer, and a second electrode which are sequentially stacked on the substrate. The light-emitting function layer and the second electrode are located within the first isolation opening. The second electrode is electrically connected to the first isolation structure. The first isolation structure is located on a side of the pixel defining layer away from the substrate.

In the above solution, the light-emitting devices can be prepared in batches based on the isolation structures to accurately control the formation locations of the light-emitting devices and the thickness of each film layer included in the light-emitting devices, thereby improving the light-emitting efficiency of the light-emitting devices and the pixels per inch (PPI) of the display panel. Furthermore, in the above process, the first encapsulation layer undergoes an etching process to form encapsulation units that independently encapsulate the light-emitting devices. In the entire etching process, the structures below the region of the first encapsulation layer to be etched are exposed to the risk of etching, and with the setting of the protective layer, the structures facing the risk of etching during the process can be protected.

Optionally, the display panel further includes a first common electrode line and a second common electrode line. The first common electrode line is located in the display region and the non-display region. The second common electrode line is located in the non-display region. The first common electrode line is located on a side of the first sub-protective layer facing away from the substrate and on a side of the pixel defining layer facing away from the substrate. The second common electrode line is located between the first sub-protective layer and the substrate. The first common electrode line is electrically connected to the second electrode and is connected to the second electrode through the first isolation structure.

Optionally, the first common electrode line and the first isolation structure are in the same layer and of the same material. In this manner, the first common electrode line can be synchronously prepared during the preparation of the first isolation structure, thereby simplifying the preparation process of the display panel.

Optionally, the layer in which the first sub-protective layer is located is located on a side, facing the substrate, of the layer in which the pixel defining layer is located. In the non-display region, the first sub-protective layer is provided with a first via, and the first planarization layer is provided with a second via connected with the first via. The first common electrode line is connected to the second common electrode line through the first via and the second via.

In a specific embodiment of the first aspect of the present disclosure, the non-display region includes a dummy sub-pixel region, and the display panel further includes a second isolation structure. The second isolation structure is located in the dummy sub-pixel region and on a side, away from the substrate, of the first sub-protective layer. The second isolation structure can protect the underlying structures, and in addition, the second isolation structure can act as a signal shield to perform signal shielding on the underlying circuits (for example, a driving circuit or signal lines connected to the driving circuit), thereby preventing these circuits from interference from external signals (for example, signals generated by the touch structure described below).

Optionally, the display panel further includes at least one bank located in the non-display region. The bank surrounds the display region. The second isolation structure is located between the bank and the display region.

In a specific embodiment of the first aspect of the present disclosure, the substrate includes a gate driving circuit. The gate driving circuit is located in the dummy sub-pixel region. The orthographic projection of the gate driving circuit on the substrate at least partially overlaps the orthographic projection of the second isolation structure on the substrate.

Optionally, the orthographic projection of the gate driving circuit on the substrate is located within the orthographic projection of the second isolation structure on the substrate. In this manner, the second isolation structure can perform signal shielding on the gate driving circuit, thereby preventing the gate driving circuit from interference from external signals.

In another specific embodiment of the first aspect of the present disclosure, the substrate includes a gate driving circuit. The gate driving circuit is located on a side of the dummy sub-pixel region away from the display region. In this manner, the second isolation structure can perform signal shielding on signal lines of the gate driving circuit, thereby preventing the signal lines from interference from external signals.

Optionally, the orthographic projection of the gate driving circuit on the substrate at least partially overlaps the orthographic projection of the first common electrode line on the substrate. In this manner, the first common electrode line can perform signal shielding on the gate driving circuit, thereby preventing the gate driving circuit from interference from external signals.

Optionally, the orthographic projection of the gate driving circuit on the substrate is located within the orthographic projection of the first common electrode line on the substrate.

In a specific embodiment of the first aspect of the present disclosure, the display panel further includes a touch structure. The touch structure is located on a side of the second encapsulation layer away from the substrate. The orthographic projection of a portion of the touch structure on the substrate overlaps the dummy sub-pixel region.

Optionally, the touch structure includes a touch electrode and a touch wire connected to the touch electrode. The touch wire is located in the display region and the non-display region. In this manner, the second isolation structure and/or the first common electrode line may shield the signals of the touch electrode or the touch wire, thereby preventing the gate driving circuit in the lower layer or the signal lines connected to the gate driving circuit from interference from these signals.

Optionally, the second isolation structure includes multiple second isolation openings. The second isolation openings expose the first sub-protective layer.

In a specific embodiment of the first aspect of the present disclosure, the display panel further includes a third encapsulation layer. The third encapsulation layer is located between the first encapsulation layer and the second encapsulation layer. The third encapsulation layer fills the second isolation openings and is in direct contact with the first sub-protective layer in the second isolation openings. In this manner, the first sub-protective layer is a continuous film layer at the second isolation openings, thereby protecting the underlying film layers during the formation of the second isolation openings.

Optionally, in the case where the third encapsulation layer is in direct contact with the first sub-protective layer in the second isolation openings, the display panel further includes a dummy electrode. The orthographic projection of the second isolation opening on the substrate is located within the orthographic projection of the dummy electrode on the substrate. The dummy electrode is used for shielding signals at the second isolation openings, thereby avoiding signal interference between the touch structure and the circuits on the substrate.

Optionally, in the case where the third encapsulation layer is in direct contact with the first sub-protective layer in the second isolation openings, the dummy electrode is electrically connected to the second isolation structure. In this manner, the dummy electrode and the second isolation structure may be equipotential, thereby eliminating the need to set a separate wire for the dummy electrode.

Optionally, in the case where the third encapsulation layer is in direct contact with the first sub-protective layer in the second isolation openings, the dummy electrode and the first electrode are in the same layer and of the same material. The first sub-protective layer is provided with a transfer hole. The dummy electrode is connected to the second isolation structure through the transfer hole. In this manner, the dummy electrode can be synchronously prepared during the preparation of the first electrode, thereby simplifying the preparation process of the display panel.

In another specific embodiment of the first aspect of the present disclosure, the display panel further includes a dummy light-emitting device. The dummy light-emitting device includes a first dummy electrode, a first dummy light-emitting function layer, and a second dummy electrode which are sequentially stacked on the substrate. The first sub-protective layer includes a dummy pixel opening communicating with the second isolation opening. The first dummy light-emitting function layer and the second dummy electrode are located in the dummy pixel opening and the second isolation opening, and the second dummy electrode is connected to the second isolation structure.

In the above solution, the dummy sub-pixel region and the display region are prepared using the same preparation process to form the dummy light-emitting device corresponding to the light-emitting device in the second isolation opening. In this manner, the second dummy electrode of the dummy light-emitting device can be connected to the second isolation structure, thereby achieving signal shielding.

In another specific embodiment of the first aspect of the present disclosure, the display panel further includes a dummy light-emitting device. The dummy light-emitting device includes a first dummy electrode, a first dummy light-emitting function layer, and a second dummy electrode which are sequentially stacked on the substrate. The first dummy electrode is spaced apart from the first dummy light-emitting function layer by the first sub-protective layer. The first dummy light-emitting function layer and the second dummy electrode are located in the second isolation opening, and the second dummy electrode is connected to the second isolation structure. In the above solution, the dummy sub-pixel region and the display region are prepared using the same preparation process to form the dummy light-emitting device corresponding to the light-emitting device in the second isolation opening. In this manner, the second dummy electrode of the dummy light-emitting device can be connected to the second isolation structure, thereby achieving signal shielding. Furthermore, the first sub-protective layer is a continuous film layer at the second isolation openings, thereby protecting the underlying film layers during the formation of the second isolation openings.

In a specific embodiment of the first aspect of the present disclosure, the first sub-protective layer includes a third opening to expose the first planarization layer in the non-display region. The orthographic projection of the third opening on the substrate is located between the orthographic projection of the first isolation structure on the substrate and the orthographic projection of the second isolation structure on the substrate.

In the above solution, the third opening may be used for releasing the gas enclosed inside the first planarization layer, thereby preventing the gas from adversely affecting the subsequent encapsulation.

In a specific embodiment of the first aspect of the present disclosure, the first isolation structure and the second isolation structure are in the same layer and of the same material. In this manner, the second isolation structure can be synchronously prepared during the preparation of the first isolation structure, thereby simplifying the preparation process of the display panel.

In a specific embodiment of the first aspect of the present disclosure, the first isolation structure includes a first support portion and a crown portion. The first support portion is located between the first crown portion and the substrate. The orthographic projection of the first support portion on the substrate is located within the orthographic projection of the first crown portion on the substrate. The second isolation structure includes a second support portion and a second crown portion. The second support portion is located between the second crown portion and the substrate. The orthographic projection of the second crown portion on the substrate is located within the orthographic projection of the second crown portion on the substrate. The first support portion and the second support portion are in the same layer and of the same material. The first crown portion and the second crown portion are in the same layer and of the same material.

A second aspect of the present disclosure provides a display panel. The display panel has a display region and a non-display region and includes a substrate and a bank, an encapsulation structure, a protective layer and multiple light-emitting devices which are located on the substrate. The light-emitting devices are located in the display region. The bank is located in the non-display region. The bank includes a top film layer away from the substrate. The encapsulation structure is stacked on a side, away from the substrate, of the bank and on a side, away from the substrate, of the light-emitting device. The protective layer is at least partially located in the non-display region.

The protective layer is located on a side, facing the substrate, of the encapsulation structure and laps the top film layer. The encapsulation structure includes a first encapsulation layer and a second encapsulation layer which are stacked. The first encapsulation layer is located on a side, facing the substrate, of the second encapsulation layer. The second encapsulation layer is located in the display region and the non-display region and is in direct contact with the bank.

In the above solution, the protective layer can protect underlying structures during the preparation process of the first encapsulation layer to avoid damage to the substrate or the structures between the substrate and the protective layer. Furthermore, the protective layer can protect the side surface of the bank during the preparation of a pixel defining layer, thereby reducing the risk of the bank being damaged by etching.

In a specific embodiment of the second aspect of the present disclosure, the protective layer and the encapsulation structure are in the same layer and of the same material type. The protective layer and the encapsulation structure are made of an inorganic material.

A third aspect of the present disclosure provides a method of preparing a display panel. The preparation method includes the following steps. A substrate is provided, and a display region and a non-display region of the display panel are pre-divided on the substrate. A protective layer is formed on the substrate, where at least a portion of the protective layer is formed in the non-display region. A light-emitting device is formed on the substrate, where the light-emitting device is formed in the display region. A first encapsulation layer and a second encapsulation layer that cover the light-emitting device are sequentially formed on a side of the light-emitting device facing away from the substrate, where the second encapsulation layer is located in the display region and the non-display region, the protective layer is formed between the second encapsulation layer and the substrate, and the second encapsulation layer is formed in direct contact with the protective layer in the non-display region. In the above preparation method, the protective layer can protect underlying structures during the preparation process of the first encapsulation layer to avoid damage to the substrate or the structures between the substrate and the protective layer, thereby ensuring the quality of the display panel.

In a specific embodiment of the third aspect of the present disclosure, the step of forming the protective layer, the pixel defining layer, the light-emitting device, and the first encapsulation layer includes the following steps. Multiple first electrodes are formed on the substrate. A pixel-defining material layer is formed on the substrate on which the first electrodes are formed. A first isolation structure is formed on a side of the pixel-defining material layer facing away from the substrate, where the first isolation structure has multiple first isolation openings. The pixel-defining material layer is patterned to form pixel openings, each of the pixel openings corresponds to a respective one of the first isolation openings, a portion of the pixel-defining material layer, which is located in the display region, is formed as a pixel defining layer, and a portion of the pixel-defining material layer, which is located in the non-display region, is formed as a first sub-protective layer of the protective layer. Light-emitting function layers and second electrodes are formed on a side, facing away from the substrate, of the first isolation structure, where the first electrode, the light-emitting function layer, and the second electrode corresponding to each of the first isolation openings constitute a light-emitting device. After a first encapsulation film is formed on a side, facing away from the substrate, of the first isolation structure and on a side, facing away from the substrate, of the light-emitting device, a photoresist is deposited on the first encapsulation film, and the photoresist is patterned to form a photoresist pattern covering part of the first isolation openings. The first encapsulation film, the light-emitting function layers, and the second electrodes are etched with the photoresist pattern as a mask to remove portions not covered by the photoresist pattern of the first encapsulation film, the light-emitting function layers, and the second electrodes, where the remaining portion of the first encapsulation film is an encapsulation unit. The residual photoresist pattern is removed. The above process from the step of forming the light-emitting function layers and the second electrodes to the step of removing the residual photoresist pattern is repeated to form the light-emitting devices and the encapsulation units at the first isolation openings where no light-emitting device is formed, where all the encapsulation units collectively constitute the first encapsulation layer.

In a specific embodiment of the third aspect of the present disclosure, the step of forming the pixel defining layer, the light-emitting device, and the first encapsulation layer includes the following steps. Multiple first electrodes are formed on the substrate. A pixel-defining material layer is formed on the substrate on which the first electrodes are formed. A first isolation structure is formed on a side of the pixel-defining material layer facing away from the substrate, where the first isolation structure has multiple first isolation openings. The pixel-defining material layer is patterned to form pixel openings each of which corresponds to a respective one of part of the first isolation openings, a portion of the pixel-defining material layer, which is located in the display region, is formed as a pixel defining layer, and a portion of the pixel-defining material layer, which is located in the non-display region, is formed as a first sub-protective layer of the protective layer. Light-emitting function layers and second electrodes are formed on a side of the first isolation structure facing away from the substrate, where the first electrode, the light-emitting function layer, and the second electrode corresponding to each of the first isolation openings constitute a light-emitting device. After a first encapsulation film is formed on a side, facing away from the substrate, of the first isolation structure and on a side, facing away from the substrate, of the light-emitting device, a photoresist is deposited on the first encapsulation film, and the photoresist is patterned to form a photoresist pattern covering part of the first isolation openings. The first encapsulation film, the light-emitting function layers, and the second electrodes are etched with the photoresist pattern as a mask to remove portions not covered by the photoresist pattern of the first encapsulation film, the light-emitting function layers, and the second electrodes, where the remaining portion of the first encapsulation film is an encapsulation unit. The residual photoresist pattern is removed. The above process from the step of forming the pixel openings to the step of removing the residual photoresist pattern is repeated to form the pixel openings each of which corresponds to a respective one of the first isolation openings in the pixel defining layer and form the light-emitting devices and the encapsulation units at the first isolation openings where no light-emitting device is formed, where all the encapsulation units collectively constitute the first encapsulation layer.

### BRIEF DESCRIPTION OF DRAWINGS

FIG. 1 is a plane view of a display panel according to an embodiment of the present disclosure;

FIG. 2 is an enlarged view of the region S1 in the display panel shown in FIG. 1.

FIG. 3A is a sectional view taken along M1-N1 of the display panel shown in FIG. 2.

FIG. 3B is a sectional view taken along M2-N2 of the display panel shown in FIG. 1 in one design.

FIG. 3C is a sectional view taken along M2-N2 of the display panel shown in FIG. 1 in another design.

FIG. 4 is a sectional view of a partial region of a display panel according to an embodiment of the present disclosure.

FIG. 5A is a sectional view taken along M1-N1 of the display panel shown in FIG. 1 in one design.

FIG. 5B is a sectional view taken along M2-N2 of the display panel corresponding to FIG. 1 and FIG. 5A.

FIG. 6A is a sectional view taken along M1-N1 of the display panel shown in FIG. 1 in another design.

FIG. 6B is a sectional view taken along M2-N2 of the display panel corresponding to FIG. 1 and FIG. 6A.

FIG. 7A is a sectional view taken along M1-N1 of the display panel shown in FIG. 1 in another design.

FIG. 7B is a sectional view taken along M2-N2 of the display panel corresponding to FIG. 1 and FIG. 7A.

FIG. 8A is a sectional view taken along M1-N1 of the display panel shown in FIG. 1 in another design.

FIG. 8B is a sectional view taken along M2-N2 of the display panel corresponding to FIG. 1 and FIG. 8A.

FIG. 9A is a sectional view taken along M1-N1 of the display panel shown in FIG. 1 in another design.

FIG. 9B is a sectional view taken along M2-N2 of the display panel corresponding to FIG. 1 and FIG. 9A.

FIG. 9C is a sectional view taken along M2-N2 of the display panel corresponding to FIG. 1 and FIG. 9A in another design.

FIG. 10A is a sectional view taken along M1-N1 of the display panel shown in FIG. 1 in another design.

FIG. 10B is a sectional view taken along M2-N2 of the display panel corresponding to FIG. 1 and FIG. 10A.

FIG. 11 is a sectional view of a partial region of a display panel according to an embodiment of the present disclosure.

FIG. 12 is a plane view of another display panel according to an embodiment of the present disclosure.

FIG. 13A is a sectional view taken along M3-N3 of the display panel shown in FIG. 12 in one design.

FIG. 13B is a sectional view taken along M3-N3 of the display panel shown in FIG. 12 in another design.

FIG. 14 is a sectional view of a partial region of another display panel according to an embodiment of the present disclosure.

FIG. 15A is a sectional view of a partial region of another display panel according to an embodiment of the present disclosure.

FIG. 15B is a sectional view of a partial region of another display panel according to an embodiment of the present disclosure.

FIG. 16A is a flowchart of a method of preparing a display panel according to an embodiment of the present disclosure.

FIG. 16B is a flowchart of another method of preparing a display panel according to an embodiment of the present disclosure.

FIG. 16C is a flowchart of another method of preparing a display panel according to an embodiment of the present disclosure.

FIGS. 17A to 17I are process views of a method of preparing the display panel shown in FIG. 3 according to an embodiment of the present disclosure.

FIG. 18 is a sectional view of a positional relationship between part of the film layers of a display panel and a vapor deposition source during vapor deposition according to an embodiment of the present disclosure.

### LIST OF REFERENCE NUMBERS

10—display panel; 11a—display region; 11b—binding region; 11c—non-display region; 11d—bending region; 11e—dummy sub-pixel region; 12—bezel region; 100—substrate; 110—common electrode line; 111—first common electrode line; 111a—first conductive layer; 111b—second conductive layer; 112—second common electrode line; 112a—air permeable hole; 121—first planarization layer; 122—second planarization layer; 123—third planarization layer; 130—gate driving circuit; 131—first signal line; 132—second signal line; 200—light-emitting device; 200a—dummy light-emitting device; 210—first electrode; 210a—first dummy electrode; 220—light-emitting function layer; 220a—first dummy light-emitting function layer; 221—first function layer; 222—light-emitting layer; 223—second function layer; 230—second electrode; 230a—second dummy electrode; 300—first isolation structure; 301—first isolation opening; 300a—second isolation structure; 301a—second isolation opening; 302—pixel opening; 310—first support portion; 310a—second support portion; 310b—first material layer; 320—first crown; 320a—second crown; 320b—second material layer; 330—pixel defining layer; 330a—pixel-defining material layer; 400—encapsulation structure; 410—first encapsulation layer; 410a—first encapsulation film; 411—encapsulation unit; 420—second encapsulation layer; 430—third encapsulation layer; 500—protective layer; 510—first sub-protective layer; 520—second sub-protective layer; 600—bank; 610—top film layer; 620—support layer; 621—first sub-support layer; 622—second sub-support layer; 800—touch structure; 810—first touch electrode layer; 820—second touch electrode layer; 830—touch wire; 900—photoresist pattern.

### DETAILED DESCRIPTION

The solutions in embodiments of the present disclosure will be described clearly and completely in conjunction with the drawings in the embodiments of the present disclosure. Apparently, the embodiments described below are part, not all, of the embodiments of the present disclosure. Based on the embodiments of the present disclosure, all other embodiments obtained by those of ordinary skill in the art without creative work are within the scope of the present disclosure.

In a display panel, a pixel defining layer is provided to define the position of a light-emitting device (for example, a light-emitting device described below), and an encapsulation layer is provided to encapsulate the light-emitting device. The process of preparing the light-emitting device and the encapsulation layer involves an etching process. In the peripheral non-display region of the display panel, the etching process will etch formed structures. If the etching is excessive, the function structures of the display panel, such as signal lines, will be damaged, thereby affecting the yield of the display panel.

The present disclosure provides a display panel and a method of the same to at least solve the above problems. The display panel has a display region and a non-display region and includes a substrate and an encapsulation structure, a protective layer and multiple light-emitting devices which are located on the substrate. The light-emitting devices are located in the display region. The encapsulation structure is located on a side of the light-emitting device away from the substrate, and the encapsulation structure includes a first encapsulation layer and a second encapsulation layer located on a side of the first encapsulation layer facing away from the substrate. The first encapsulation layer and the second encapsulation layer cover the light-emitting device. The orthographic projection of the second encapsulation layer on the substrate is located in the display region and the non-display region. The protective layer is at least partially located in the non-display region and located on a side of the second encapsulation layer facing the substrate. The protective layer is in direct contact with the second encapsulation layer in the non-display region. The protective layer and the second encapsulation layer are of the same type of materials. In the display panel, the protective layer can protect underlying structures during the preparation process of the first encapsulation layer to avoid damage to the substrate or the structures between the substrate and the protective layer, thereby ensuring the quality of the display panel. Furthermore, the protective layer and the second encapsulation layer have a same material, the bonding strength between the protective layer and the second encapsulation layer is high to reduce the risk of the second encapsulation layer being detached, thereby improving the encapsulation effect of the display panel.

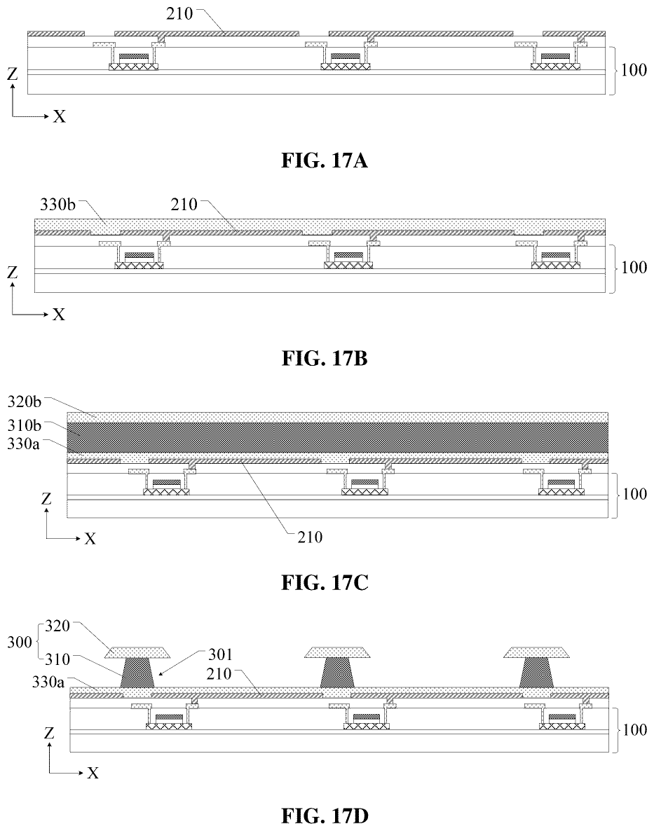

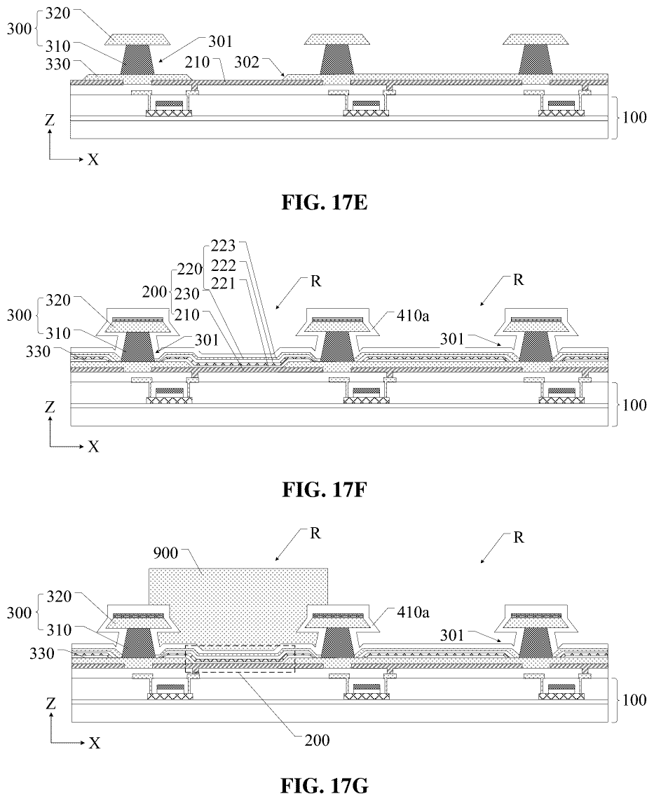

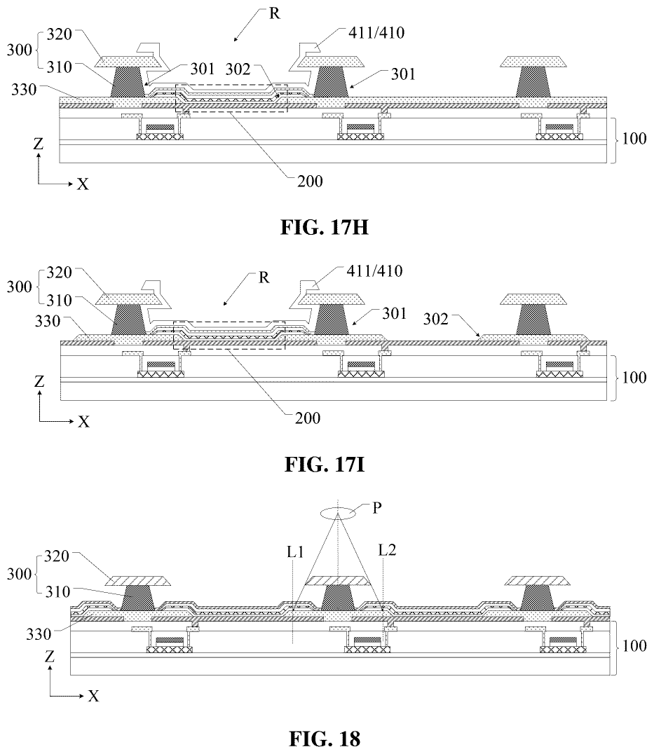

It is to be noted that for the manner of forming the first encapsulation layer and the principle behind the risk of over-etching in the pixel defining layer, reference may be made to the specific descriptions in the embodiments related to FIGS. 17A to 17I below, and the details are not repeated here.

The structure of a display panel according to at least one embodiment of the present disclosure will be described below in detail in conjunction with the drawings. Furthermore, in those drawings, a space rectangular coordinate system is established with the substrate as a reference to more intuitively present the positional relationships of the related structures in the display panel. In the space rectangular coordinate system, the X-axis and the Y-axis are parallel to the plane where the substrate is located, and the Z-axis is perpendicular to the plane where the substrate is located.

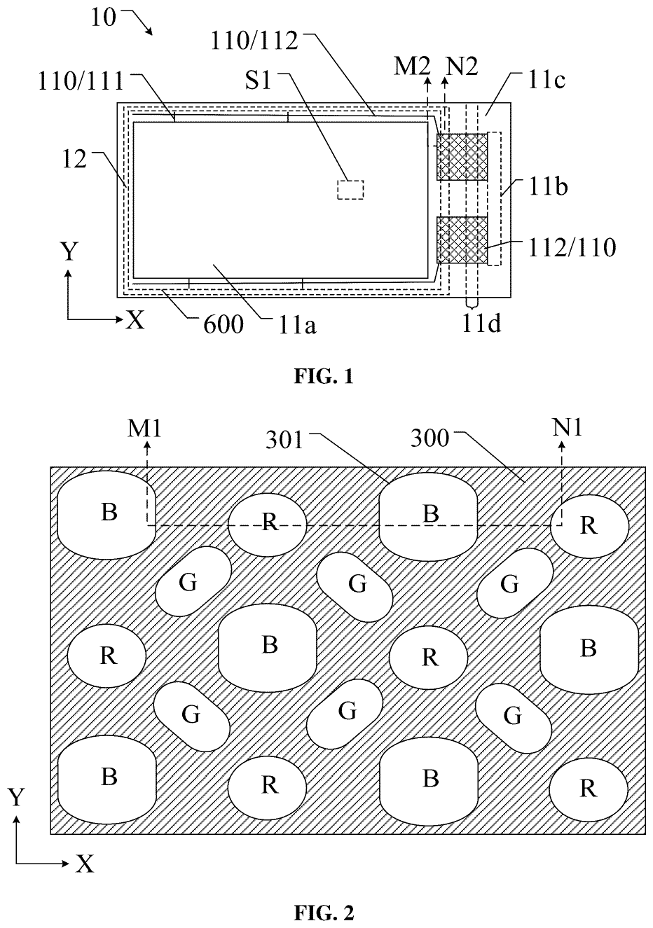

As shown in FIGS. 1, 2, 3A, and 3B, the planar region of the display panel 10 may be divided into a display region 11 and a bezel region 12 surrounding the display region 11. Sub-pixels, such as red (R), green (G), and blue (B) sub-pixels, may be arranged in the display region 11, and the physical structure of the sub-pixel may be a light-emitting device in the following embodiments. Sub-pixels which are adjacent to each other and emit light of different colors form one pixel (which may be referred to as a pixel unit, a large pixel, or the like), and the layout density of the pixels in the display region 11 represents the PPI. It is to be noted that in some embodiments of the present disclosure, part of the wires in the bezel region 12 may be arranged into the display region 11 so that the bezel region 12 may be designed as a single-side bezel.

The physical structure of the display panel 10 may include a substrate 100 and an encapsulation structure, a protective layer 500 and multiple light-emitting devices 200 which are located on the substrate. The light-emitting devices 200 are located in the display region 11a. The encapsulation structure is located on a side of the light-emitting device 200 away from the substrate 100, and the encapsulation structure includes a first encapsulation layer 410 and a second encapsulation layer 420 located on a side of the first encapsulation layer 410 facing away from the substrate 100. The first encapsulation layer 410 and the second encapsulation layer 420 cover the light-emitting device 200. The orthographic projection of the second encapsulation layer 420 on the substrate 100 is located in the display region 11a and the non-display region 11c. The protective layer 500 is at least partially located in the non-display region 11c and located on a side of the second encapsulation layer 420 facing the substrate 100. The protective layer 500 is in direct contact with the second encapsulation layer 420 in the non-display region 11c. The protective layer 500 and the second encapsulation layer 420 are of the same material type to enable a high bonding strength between the protective layer 500 and the second encapsulation layer 420. In this manner, the protective layer 500 can protect the underlying structures during the preparation process of the first encapsulation layer 410 to avoid damage to the substrate 100 or the structures between the substrate 100 and the protective layer 500, thereby ensuring the quality of the display panel. It is to be noted that the same material type refers to the same broad category of materials. For example, both the protective layer 500 and the second encapsulation layer 420 are made of organic materials or inorganic materials, and the same broad category of materials may have a high bonding strength between them.

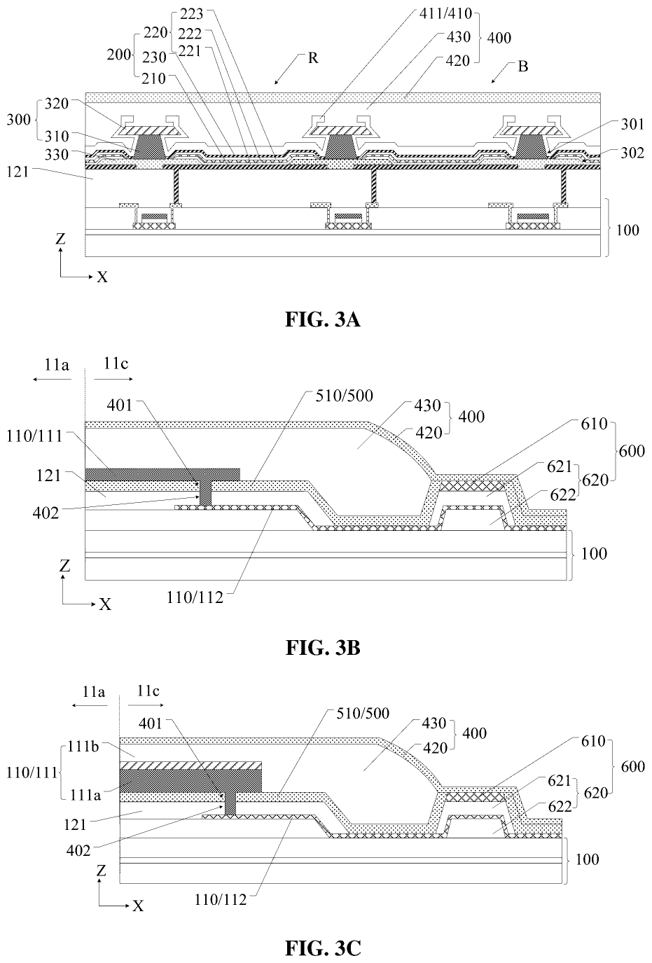

In at least one embodiment of the present disclosure, as shown in FIG. 3A, the light-emitting device 200 may include a first electrode 210, a light-emitting function layer 220, and a second electrode 230 which are sequentially stacked on the substrate 100 in a direction away from the substrate 100. The light-emitting function layer 220 may further include a light-emitting layer 222 and a second function layer 223. The first function layer 221, the light-emitting layer 222, and the second function layer 223 are sequentially stacked on the first electrode 210. The first function layer 221 may include a hole injection layer, a hole transport layer, an electron blocking layer, and the like. The second function layer 223 may include an electron injection layer, an electron transport layer, a hole blocking layer, and the like. It is to be noted that one or more light-emitting layers 222 may be provided in the light-emitting device 200. In the case where multiple light-emitting layers 222 are provided, the light-emitting device 200 may have higher light emission efficiency.

For example, in at least one embodiment of the present disclosure, the first electrode 210 may be provided as an anode, and the second electrode 230 may be provided as a cathode.

In at least one embodiment of the present disclosure, the substrate 100 may include a base and a driving circuit layer located on the base. The driving circuit layer includes multiple pixel driving circuits located in the display region, and the display function layer is located on the drive circuit layer. For example, the pixel driving circuit may include multiple thin film transistors (TFTs), a capacitor, and the like and may be formed in various forms such as 2T1C (that is, two transistors (TFTs) and one capacitor (C)), 3T1C or 7T1C. The pixel driving circuit is connected to the light-emitting device 200 to control the switch state and light emission brightness of the light-emitting device 200.

In at least one embodiment of the present disclosure, as shown in FIG. 3A, the display panel further includes a pixel defining layer 330 located on the substrate 100. The pixel defining layer 330 is located in the display region 11a and is provided with multiple pixel openings 302. The pixel opening 302 are used for accommodating light-emitting devices 200. The protective layer 500 includes a first sub-protective layer 510. The first sub-protective layer 510 laps the pixel defining layer 330. The first sub-protective layer 510 and the second encapsulation layer 420 are in direct contact in the non-display region 11c. In this manner, by lapping the first sub-protective layer 510 and the pixel defining layer 330, the existence of a gap between the first sub-protective layer 510 and the pixel defining layer 330 is avoided, thereby improving the protective effect on the underlying structures during the preparation process of the first encapsulation layer 410.

As shown in FIG. 3A, the first electrode 210 is located between the pixel defining layer 330 and the substrate 100. The pixel opening 302 exposes a partial region of the first electrode 210. The light-emitting function layer 220 and the second electrode 230 cover the pixel opening 302 and extend to a side of the pixel defining layer 330 facing away from the substrate 100. The pixel opening 302 defines the effective region of the first electrode 210, and the effective region corresponds to the effective light-emitting region of the light-emitting device 200. In this manner, the pixel opening 302 actually defines the light-emitting region (for example, the position, the region, and the like) of the light-emitting device 200 (or referred to as a sub-pixel).

In at least one embodiment of the present disclosure, the pixel defining layer 330, the first encapsulation layer 410, the second encapsulation layer 420, and the protective layer 500 are inorganic film layers. When the same materials are in contact, the interlayer adhesion is improved, thereby achieving better structural stability and a better encapsulation effect.

In at least one embodiment of the present disclosure, the material of the pixel defining layer 330, the first encapsulation layer 410, the second encapsulation layer 420, and the protective layer 500 include one of silicon oxide, silicon nitride or silicon oxynitride.

In some scenarios, some function film layers in the light-emitting device are formed by vapor deposition, each light-emitting device has a variety of function film layers, and some function film layers (for example, the light-emitting layer) in the light-emitting devices emitting light of different colors have different material compositions. When these function film layers are vapor-deposited through a mask (for example, a fine mask), alignment needs to be performed several times. To solve the position offset caused by an alignment precision error, it is necessary to reserve enough space (and a safety margin related to an alignment error) between different light-emitting devices to ensure that the position of the actual light-emitting region of the light-emitting device and the design position (the design area) has a certain overlap. The above operation equivalently compresses the design area of the light-emitting region of the light-emitting device, thereby limiting the light-emitting area of the light-emitting device, making the layout density of the light-emitting devices fail to be further increased, and thus making it difficult to further increase the PPI of the display panel.

In the embodiments of the present disclosure, an isolation structure (the first isolation structure described below) is provided at the gap between the light-emitting devices to isolate the function film layers of the adjacent light-emitting devices. In this manner, in the vapor deposition process of the function film layers, the function film layers of each light-emitting device do not have to be prepared individually using masks, but the function film layers are vapor-deposited on the whole surface of the display panel. The process does not need to consider the problem of the alignment precision during vapor deposition and can enable the gap between the light-emitting devices to be designed smaller in size, thereby increasing the PPI (the principle behind which can be seen in the descriptions in the embodiments related to FIGS. 17A to 17I below). It is to be noted that when the light-emitting devices are prepared based on the above isolation structure, the light-emitting devices will be prepared in batches, and the first encapsulation layer needs to encapsulate each light-emitting device independently during the above preparation process to protect the light-emitting devices. Therefore, the first encapsulation layer is also formed through multiple etching processes, and the first encapsulation layer is formed into multiple encapsulation units. In the above process, multiple etching processes are involved, and therefore, in the case where the non-display region is not provided with a protective layer, these etching processes will damage the structures in the non-display region.

In at least one embodiment of the present disclosure, as shown in FIGS. 2 and 3A, the display panel further includes a first isolation structure 300. The first isolation structure 300 is located in the display region 11a and is provided with multiple first isolation openings 301. The first isolation opening 301 is communicated with the pixel opening 302. The first encapsulation layer 410 includes multiple encapsulation units 411. The encapsulation unit 411 is located on a side of the light-emitting device 200 facing away from the substrate 100. The light-emitting device 200 includes a first electrode 210, a light-emitting function layer 220, and a second electrode 230 which are sequentially stacked on the substrate 100. The light-emitting function layer 220 and the second electrode 230 are located within the first isolation opening 301. The second electrode 230 is electrically connected to the first isolation structure 300. The first isolation structure 300 is located on a side of the pixel defining layer 330 away from the substrate 100. The light-emitting devices 200 can be prepared in batches based on the isolation structures to accurately control the formation locations of the light-emitting devices 200 and the thickness of each film layer included in the light-emitting devices 200, thereby improving the light-emitting efficiency of the light-emitting devices 200 and the PPI of the display panel. Furthermore, in the above process, the first encapsulation layer 410 undergoes an etching process to form encapsulation units 411 that independently encapsulate the light-emitting devices 200. In the entire etching process, the structures below the region of the first encapsulation layer 410 to be etched are exposed to the risk of etching, and with the setting of the protective layer 500, the structures facing the risk of etching during the above process can be protected.

In at least one embodiment of the present disclosure, as shown in FIG. 3A, the first isolation structure 300 is located between the pixel defining layer 330 and the first encapsulation layer 410, and the isolation structure 300 includes a first support portion 310 and a crown portion 320. The first support portion 310 is located between the first crown portion 320 and the substrate 100. The orthographic projection of the first support portion 310 on the substrate 100 is located within the orthographic projection of the first crown portion 320 on the substrate 100. That is, the first isolation structure 300 is wide at the top and narrow at the bottom as a whole, and part of the film layers (for example, the light-emitting function layer 220) in the light-emitting device 200 are disconnected at the edges of the first isolation structure 300 when the film layers are vapor-deposited, thereby reducing the risk of adjacent light-emitting devices 200 being subjected to crosstalk.

In some embodiments of the present disclosure, the main structure of the first isolation structure 300 may tend to be prepared by using a conductive material, thereby reducing the voltage for driving the second electrode 230. For example, as shown in FIG. 3A, the first support portion 310 is a conductive structure, and the second electrode 230 is electrically connected to the side surface of the first support portion 310. In this manner, the first support portion 310 may be used for assisting in connecting the second electrode 230. Since the first support portion 310 is located at the gap between the light-emitting devices 200, the first support portion 310 can have a higher design thickness (greater than the thickness of the second electrode 230) and can be prepared using a high conductivity material, thereby reducing the voltage drop problem on the second electrode 230 when the light-emitting device 200 is driven in the case where the first support portion 310 is connected to the second electrode 230.

For example, as shown in FIG. 3A, on the basis that the first support portion 310 is a conductive structure, the first crown portion 320 may also be further designed to be a conductive structure, thereby reducing the voltage drop problem on the second electrode 230 when the light-emitting device 200 is driven.

For example, as shown in FIG. 3A, on the basis that the first support portion 310 is a conductive structure, the first crown portion 320 and the first support portion 310 may be prepared from titanium and aluminum respectively, with the corrosion resistance of titanium and aluminum decreasing in sequence, so that the first isolation structure 300 shown in FIG. 3A may be formed.

In at least one embodiment of the present disclosure, with reference to FIG. 3A, the pixel defining layer 330 is an inorganic insulating film layer. In the case where the light-emitting device is prepared using the first isolation structure 300, the thickness of the pixel defining layer 330 does not need to be large to accommodate and insulate part of the film layers in the light-emitting device 200, thereby allowing the pixel defining layer 330 to be prepared directly using an inorganic material. In this manner, the pixel defining layer 330 can space the first isolation structure 300 apart from the first electrode 210 so that the gap between the first electrodes 210 is designed to be smaller and the pixel gap is reduced, thereby increasing the PPI of the display panel. Furthermore, the inorganic layer has a high degree of densification and a high resistive capacity, thereby reducing the design thickness of the display panel. Moreover, the thickness of the inorganic film layer is relatively small so that the pixel opening 302 has a small depth, thereby ensuring the film continuity of the film layers (for example, the second electrode 230) formed at the pixel opening 302. In addition, as an inorganic film layer, the pixel defining layer 330 may have a greater bonding strength with the isolation structure 300, thereby reducing the risk of the isolation structure 300 being detached.

In at least one embodiment of the present disclosure, with reference to FIG. 3A, the first encapsulation layer 410 is provided with multiple encapsulation units 411. Each encapsulation unit 411 corresponds to a respective one of the first isolation openings 301 and covers the light-emitting device 200 in the corresponding first isolation opening 301. In the process of preparing the light-emitting devices 200 in batches based on the isolation structures 300, the encapsulation units 411 and the corresponding light-emitting devices 200 are formed simultaneously. After one batch of light-emitting devices 200 are prepared, in the process of preparing the next batch of light-emitting devices 200, the encapsulation units 411 can encapsulate and protect the light-emitting devices 200 that have been prepared, thereby ensuring the light-emitting efficiency of the light-emitting devices 200.

In the case where the light-emitting devices 200 are various types of light-emitting devices 200 that emit light of different colors, the light-emitting devices 200 that emit light of each different color are prepared independently, but the film layers (vapor-deposited film layers such as the light-emitting function layer) in each of the light-emitting devices 200 are vapor-deposited on the whole surface of the display panel during vapor deposition. For example, the light-emitting devices 200 are classified as light-emitting devices that emit red light (R), green light (G), and blue light (B), respectively. During the preparation process, the light-emitting devices R, G, and B are prepared sequentially. In the preparation of the light-emitting devices R, a light-emitting device R is formed in each of the first isolation openings 301, the first encapsulation layer 410 is prepared on the display panel to cover the light-emitting devices R, and then the first encapsulation layer 410 and the second electrodes and the light-emitting function layers of the light-emitting devices R are removed from part of the first isolation openings 301 (which are used for forming the light-emitting devices G and B in the final product) to obtain the encapsulation units 411. In the above process, the first encapsulation layer 410 is used for protecting the light-emitting devices R in other first isolation openings 301. Based on the above manner, the light-emitting devices G and B are then sequentially prepared to ultimately form the first encapsulation layer 410 shown in FIG. 3A. That is, the preparation of the first encapsulation layer 410 on the entire display panel is divided into multiple processes.

It is to be noted that in the embodiments of the present disclosure, the order of preparation of the three types of light-emitting devices R, G, and B is not limited and may be designed according to the requirements of the actual process. For example, the preparation process may also be implemented based on the order of sequentially preparing the light-emitting devices B, G, and R.

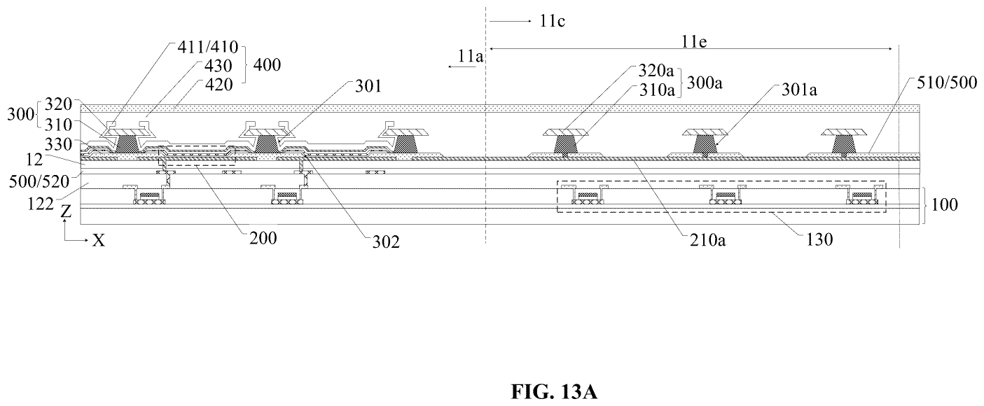

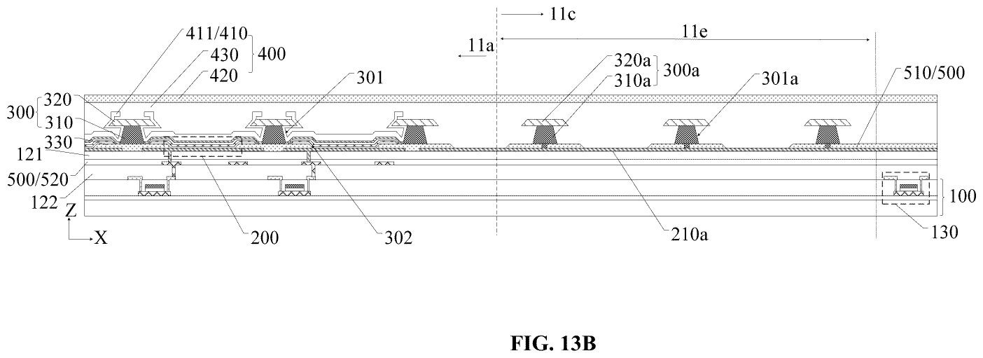

The reason why the first encapsulation layer 410 is provided with multiple encapsulation units 411 is related to the principle of the preparation of the light-emitting device 200 based on the first isolation structure 300, for which reference may be made to the descriptions in the embodiments related to FIGS. 13A to 13I below, and the details are not repeated here.

In at least one embodiment of the present disclosure, as shown in FIGS. 3A and 3B, the display panel includes a common electrode line 110. The common electrode line 110 includes a first common electrode line 111 and a second common electrode line 112. The first common electrode line 111 is connected to the second electrode 230 of the light-emitting device 200 and extends from the display region 11a to the non-display region 11c. The second common electrode line 112 is located in the non-display region 11c. The first common electrode line 111 is located on a side of the first sub-protective layer 510 facing away from the substrate 100 and on a side of the pixel defining layer 330 facing away from the substrate 100. The second common electrode line 112 is located between the first sub-protective layer 510 and the substrate 100. The first common electrode line 111 is electrically connected to the second electrode 230. In the non-display region 11c, the first common electrode line 111 and the second common electrode line 112 which are located in different layers are connected to each other. The major portion (the second common electrode line 112) of the common electrode line 110 in the non-display region 11c can be covered by the first sub-protective layer 510, thereby reducing the risk of the common electrode line being damaged during the preparation process of the first encapsulation layer 410 and the light-emitting device 200.

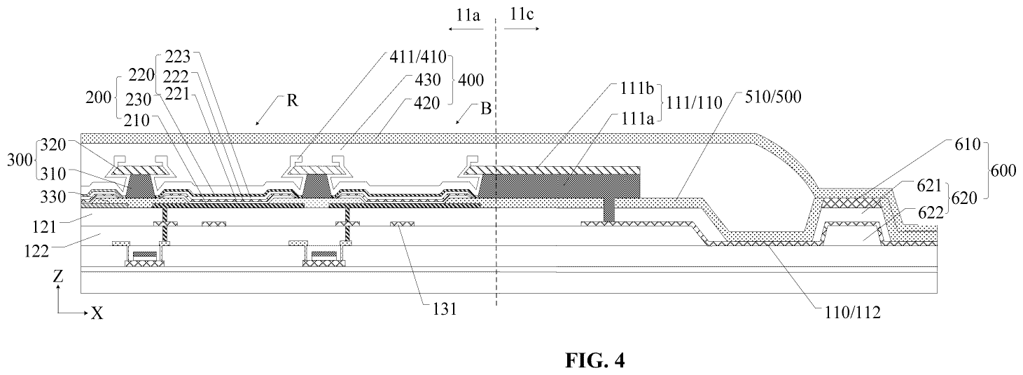

In at least one embodiment of the present disclosure, as shown in FIGS. 3A and 4, the first common electrode line 111 may be connected to the first isolation structure 300 to be indirectly connected to the second electrode 230 of the light-emitting device 200 through the first isolation structure 300.

In some embodiments of the present disclosure, as shown in FIG. 3B, the first common electrode line 111 may be separately provided to be connected to the first isolation structure 300. In this case, the preparation material of the first common electrode line 111 may be selected according to the process requirements, and the parameters such as the thickness of the first common electrode line 111 may be freely set.

In some embodiments of the present disclosure, as shown in FIGS. 3C and 4, the first common electrode line 111 and the conductive portion in the first isolation structure 300 may be in the same layer and of the same material. In this manner, the first common electrode line 111 is synchronously prepared during the preparation of the first isolation structure 300, thereby simplifying the preparation process of the display panel. For example, the first common electrode line 111 includes a first conductive layer 111a and a second conductive layer 111b which are stacked on one another. The first conductive layer 111a and the first support portion 310 are in the same layer and of the same material, and the second conductive layer 111b and the first crown portion 320 are in the same layer and of the same material.

For the setting of the first isolation structure, reference may further be made to the content in patents CN118251982A, 202410864269.8, PCT/CN2024/098407, PCT/CN2024/102783, PCT/CN2024/098217, PCT/CN2024/100935, PCT/CN2024/102785, PCT/CN2024/099419, PCT/CN2024/099072, and CN116685174A, and the details are not repeated here.

In the embodiments of the present disclosure, no limitation is made on the structure of the protective layer as long as the protective layer can protect the structures in the non-display region during the preparation of, for example, the first isolation structure, the light-emitting devices, and the first encapsulation layer, and the protective layer may be set according to the actual process requirements. Several setting manners for the protective layer will be described through different embodiments.

In some embodiments of the present disclosure, the first sub-protective layer and the pixel defining layer are arranged in the same layer. For example, as shown in FIGS. 3A and 3B, the first sub-protective layer 510 and the pixel defining layer 330 are in the same layer and of the same material. In this manner, the first sub-protective layer 510 can be synchronously prepared during the preparation of the pixel defining layer 330, thereby simplifying the preparation process of the display panel.

For example, as shown in FIGS. 3A and 3B, in the case where the first sub-protective layer 510 and the pixel defining layer 330 are in the same layer and of the same material, the first sub-protective layer 510 is located outside the display region 11a, that is, the orthographic projection of the first sub-protective layer 510 on the substrate 100 is located in the non-display region 11c.

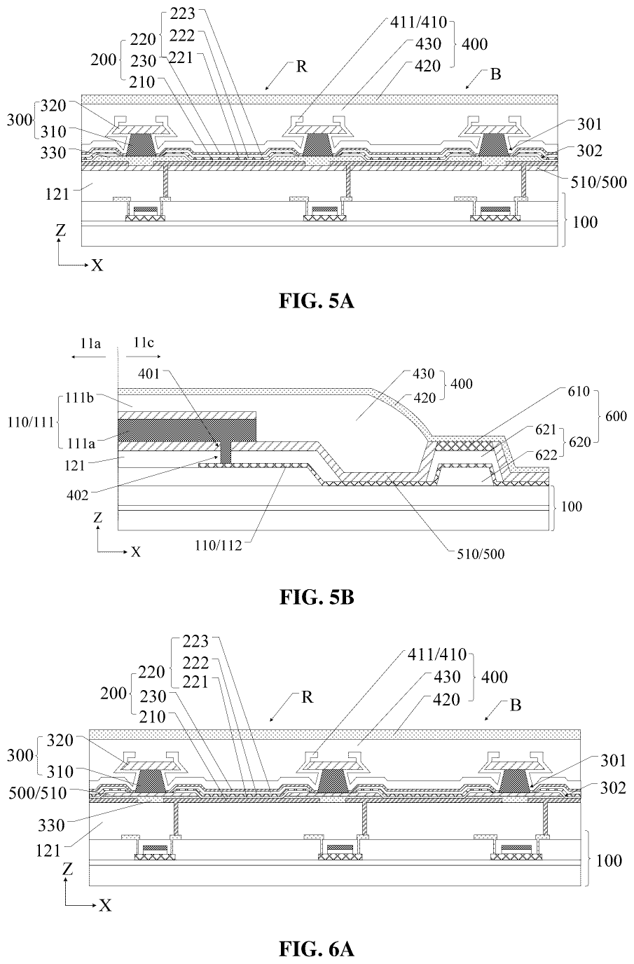

In other embodiments of the present disclosure, the first sub-protective layer is located below the pixel defining layer. For example, as shown in FIGS. 5A and 5B, the layer in which the first sub-protective layer 510 is located is located on a side, facing the substrate 100, of the layer in which the pixel defining layer 330 is located. The orthographic projection of the first sub-protective layer 510 on the substrate 100 is located in the display region 11a and the non-display region 11c. The first sub-protective layer 510 at least partially overlaps the pixel defining layer 330 in the display region 11a. The first sub-protective layer 510 is located between the pixel defining layer 330 and the substrate 100. In this manner, in the process of forming the pixel defining layer 330, the first sub-protective layer 510 formed before the pixel defining layer 330 can protect the underlying structures, thereby ensuring the quality of the display panel.

For example, as shown in FIGS. 5A and 5B, in the case where the layer in which the first sub-protective layer 510 is located is located on a side, facing the substrate 100, of the layer in which the pixel defining layer 330 is located, the orthographic projection of the pixel defining layer 330 on the substrate 100 is located within the orthographic projection of the first sub-protective layer 510 on the substrate 100. In this manner, the first sub-protective layer 510 covers the entire display region 11a, thereby protecting the structures under the pixel defining layer 330 in the display region 11a during the formation of the pixel defining layer 330.

For example, as shown in FIGS. 5A and 5B, in the case where the layer in which the first sub-protective layer 510 is located is located on a side, facing the substrate 100, of the layer in which the pixel defining layer 330 is located, the first sub-protective layer 510 is located between the first electrode 210 and the substrate 100. In this manner, the setting of the first sub-protective layer 510 does not affect the manners of setting and forming the first electrode 210. Furthermore, the bonding strength between the first electrode 210 and the substrate 100 (through the first sub-protective layer 510) can be strengthened, thereby reducing the risk of the first electrode 210 being detached.

For example, as shown in FIGS. 5A and 5B, in the case where the layer in which the first sub-protective layer 510 is located is located on a side, facing the substrate 100, of the layer in which the pixel defining layer 330 is located, the display panel further includes a first planarization layer 121 located between the substrate 100 and the first electrode 210. The first planarization layer 121 extends from the display region 11a to the non-display region 11c and is in contact with the first sub-protective layer 510 in the non-display region 11c. The first sub-protective layer 510 is located between the first electrode 210 and the first planarization layer 121 in the display region 11a. The first sub-protective layer 510 can protect the first planarization layer 121 during the preparation process of the first encapsulation layer 410 to prevent the first planarization layer 121 from being damaged, thereby ensuring the quality of the display panel.

The first planarization layer 121 is used for planarizing the underlying circuits (for example, the above-mentioned driving circuit), thereby, in one aspect, providing a planarized surface for setting the first electrode 230, and in another aspect, protecting the underlying circuits.

For example, as shown in FIGS. 5A and 5B, in the case where the layer in which the first sub-protective layer 510 is located is located on a side, facing the substrate 100, of the layer in which the pixel defining layer 330 is located, in the non-display region 11c, the first sub-protective layer 510 is provided with a first via 401, and the first planarization layer 121 is provided with a second via 402 connected with the first via 401. The first common electrode line 111 is connected to the second common electrode line 112 through the first via 401 and the second via 402. The first sub-protective layer 510 and the first planarization layer 121 are provided with the first via 401 and the second via 402 respectively for connecting the first common electrode line 111 and the second common electrode line 112 to ensure that while the common electrode line is connected to the second electrode 230, the major portion (the second common electrode line 112) of the common electrode line in the non-display region 11c can be covered by the first sub-protective layer 510 and the first planarization layer 121, thereby reducing the risk of the common electrode line being damaged during the preparation process of the first encapsulation layer 410 and the light-emitting device 200.

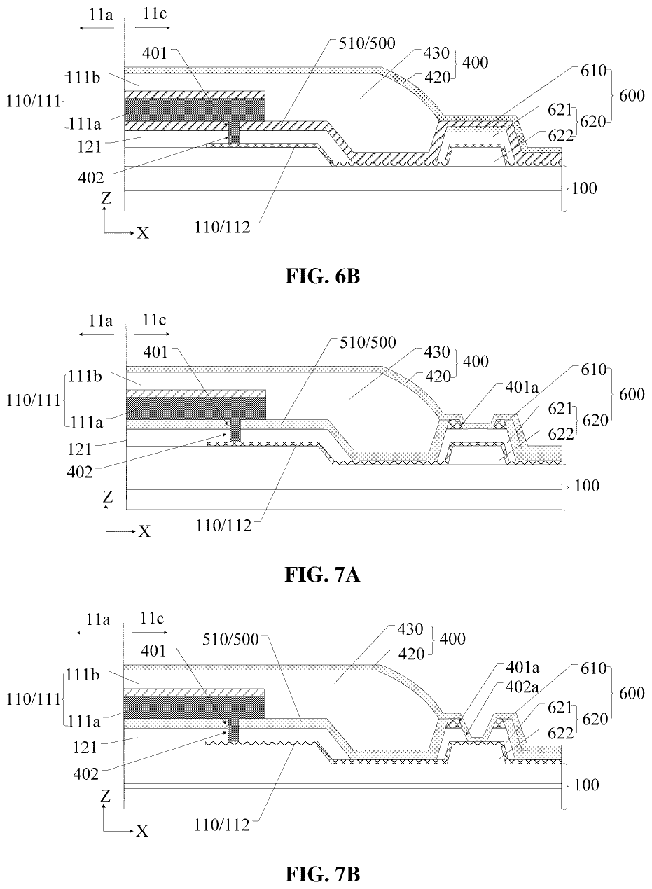

In other embodiments of the present disclosure, the first sub-protective layer is located above the pixel defining layer. For example, as shown in FIGS. 6A and 6B, the layer in which the first sub-protective layer 510 is located is located on a side, facing away from the substrate 100, of the layer in which the pixel defining layer 330 is located. The orthographic projection of the first sub-protective layer 510 on the substrate 100 is located in the display region 11a and the non-display region 11c, the first sub-protective layer 510 at least partially overlaps the pixel defining layer 330 in the display region 11a, and the pixel defining layer 330 is located between the first sub-protective layer 510 and the substrate 100. In this manner, the first sub-protective layer 510 covers the edge portion of the pixel defining layer 330 to edge-wrap the pixel defining layer 330, thereby reducing the risk of the occurrence of cracks on the edges of the pixel defining layer 330.

For example, as shown in FIGS. 6A and 6B, in the case where the layer in which the first sub-protective layer 510 is located is located on a side, facing away from the substrate 100, of the layer in which the pixel defining layer 330 is located, the light-emitting device 200 includes a first electrode 210, a light-emitting function layer 220, and a second electrode 230 which are sequentially stacked on the substrate 100, and the orthographic projection of the first sub-protective layer 510 on the substrate 100 is located outside the orthographic projection of the first electrode 210 on the substrate 100. In this manner, the setting of the first sub-protective layer 510 does not affect the manners of setting and forming the first electrode 210, thereby ensuring the quality of the light-emitting device 200.

For example, as shown in FIGS. 6A and 6B, in the case where the layer in which the first sub-protective layer 510 is located is located on a side, facing away from the substrate 100, of the layer in which the pixel defining layer 330 is located, the first planarization layer 121 may be in contact with the first sub-protective layer 510 in the non-display region 11c.

In at least one embodiment of the present disclosure, with reference to FIGS. 1, 5A, and 5B, the display panel further includes at least one bank 600 located in the non-display region 11c. The bank 600 surrounds at least a portion of the display region 11a. The bank 600 includes a top film layer 610 on a side away from the substrate 100. The first sub-protective layer 510 laps the top film layer 610. The first sub-protective layer 510 covers the side surface of the bank 600. The first sub-protective layer 510 can protect the side surface of the bank 600 during the preparation of the pixel defining layer 330, thereby reducing the risk of the bank 600 being damaged by etching.

For example, as shown in FIG. 5B, the top film layer 610 is an inorganic film layer. In this manner, in the case where the first sub-protective layer 510 is an inorganic film layer, the top film layer 610 and the first sub-protective layer 510 can be bound to each other with a high bonding strength, thereby reducing the risk of the top film layer 610 and the first sub-protective layer 510 being detached from the substrate 100. Furthermore, the top film layer 610, which is an inorganic film layer, has a high degree of densification, thereby preventing water and oxygen from invading the interior of the bank 600.

In some embodiments of the present disclosure, as shown in FIG. 5B, the first sub-protective layer 510 and the pixel defining layer 610 are in the same layer and of the same material. In this manner, the top film layer 610 can be synchronously prepared during the preparation of the first sub-protective layer 510, thereby simplifying the preparation process of the display panel.

In other embodiments of the present disclosure, as shown in FIGS. 6A and 6B, the first sub-protective layer 510 covers the top film layer 610, the first sub-protective layer 510 is located on a side, facing away from the substrate 100, of the top film layer 610, and the orthographic projection of the top film layer 610 on the substrate 100 is located within the orthographic projection of the first sub-protective layer 510 on the substrate 100. In this manner, the first sub-protective layer 510 covers the top film layer 610 to protect the top film layer 610 during the preparation process of the pixel defining layer 330, thereby reducing the risk of the bank 600 being damaged by etching.

In other embodiments of the present disclosure, as shown in FIGS. 7A and 7B, the top film layer 610 includes multiple first openings 410a. The orthographic projection of the first sub-protective layer 510 on the substrate 100 is located outside the orthographic projection of the first opening 410a on the substrate 100, and the orthographic projection of the first opening 401a on the substrate 100 is located within the orthographic projection of the second encapsulation layer 420 on the substrate 100. The second encapsulation layer 420 covers and fills the first openings 401a. The first opening 401a may be used for releasing the gas enclosed inside the bank 600, thereby ensuring the encapsulation effect of the display panel. Furthermore, the second encapsulation layer 420 covers and fills the first openings 401a to seal the first openings 401a, thereby preventing the gas from invading the bank 600 or the residual gas in the bank 600 from escaping during the subsequent preparation processes. In addition, with the setting of the first opening 401a, the second encapsulation layer 420 is embedded in the bank 600 equivalently, thereby reducing the risk of the second encapsulation layer 420 being detached from the substrate 100.

It is to be noted that if the gas in the bank 600 is not released in advance, when the gas escapes after the preparation of the display panel is completed, the escaped gas leads to interfacial delamination of the top film layer 610, the first sub-protective layer 510, and the second encapsulation layer 420, and even the gas intrudes into the encapsulation structure 400, thereby leading to a failure in encapsulation of the display panel.

In at least one embodiment of the present disclosure, as shown in FIG. 7A, the bank 600 includes a support layer 620. The support layer 620 is located between the top film layer 610 and the substrate 100, and the first sub-protective layer 510 covers the side surface of the support layer 620. In this manner, the top film layer 610 and the first sub-protective layer 510 fully cover the support layer 620 to protect the support layer 620.

For example, as shown in FIG. 7A, the first opening 401a on the top film layer 610 may release the gas enclosed inside the support layer 620, thereby ensuring the encapsulation quality of the display panel.

Optionally, the support layer 620 is an organic film layer. The thickness of the organic film layer is larger, thereby enabling the height of the bank 600 to be easily increased. Accordingly, although the organic film layer is also easily etched, in the case where the support layer 620 is covered by the top film layer 610 and the first sub-protective layer 510, the risk of the support layer 620 being etched is reduced.

In at least one embodiment of the present disclosure, as shown in FIG. 7A, at least a portion of the support layer 620 and the first planarization layer 121 are in the same layer, and the support layer 620 and the first planarization layer 121 are of the same material. The first planarization layer 121 is spaced apart from the bank 600. In this manner, the support layer 620 can be synchronously prepared during the preparation of the first planarization layer 121, thereby simplifying the preparation process of the display panel.

For example, as shown in FIG. 7A, the support layer 620 includes a first sub-support layer 621 and a second sub-support layer 622 which are stacked on one another. The second sub-support layer 622 is located between the first sub-support layer 621 and the substrate 100. The first sub-support layer 621 and the first planarization layer 121 are in the same layer and of the same material. For example, the second sub-support layer 622 is prepared in the same layer and with the same material as a film layer structure (for example, an insulating film layer) between the first sub-support layer 621 and the substrate 100 or a film layer structure (for example, an insulating film layer)) in the substrate 100.

For example, in at least one embodiment of the present disclosure, as shown in FIG. 7B, the first sub-support layer 621 is provided with multiple second openings 402a, and each of second openings 402a corresponds to a respective one of the first openings 401a. The second openings 402a are arranged at intervals along the bank 600. The first openings 401a and the second openings 402a can release the gas enclosed inside the first sub-support layer 621 and the second sub-support layer 622 (the portion not covered by the second common electrode line 112), thereby ensuring the encapsulation effect of the display panel.

In at least one embodiment of the present disclosure, as shown in FIG. 7B, the display panel further includes a third encapsulation layer 430. The third encapsulation layer 430 is located between the first encapsulation layer 410 and the second encapsulation layer 420. The third encapsulation layer 430 is located on a side of the bank 600 facing the display region 11a. The first sub-protective layer 510 is in direct contact with the third encapsulation layer 430 between the bank 600 and the display region 11a.

For example, the third encapsulation layer 430 is an organic film layer. The third encapsulation layer 430 may be formed by inkjet printing, thereby achieving a good leveling effect, and the bank 600 can block the extension of the ink, thereby defining the distribution region of the third encapsulation layer 430. In the embodiments of the present disclosure, the third encapsulation layer 430 is sandwiched between the first sub-protective layer 510 and the second encapsulation layer 420 to protect the third encapsulation layer 430. The first sub-protective layer 510 is in contact with the second encapsulation layer 420, thereby preventing external water and oxygen from invading the third encapsulation layer 430.

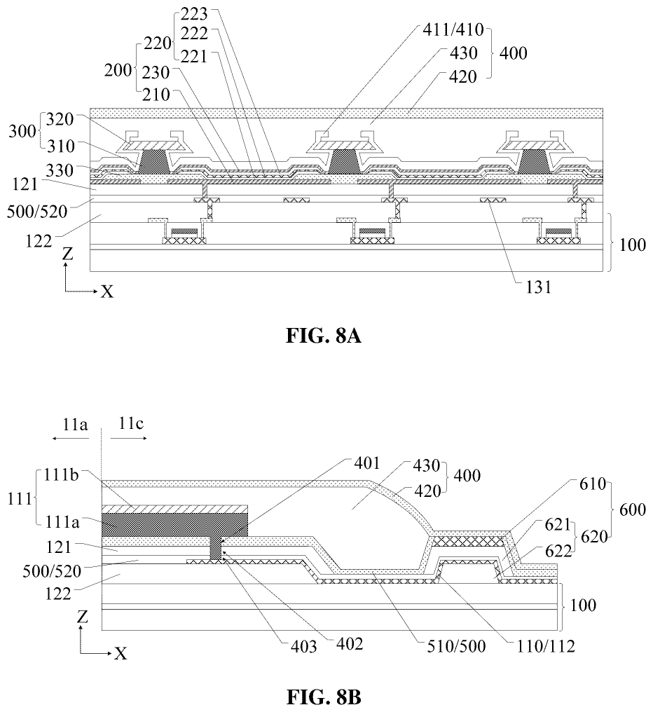

In at least one embodiment of the present disclosure, the protective layer may be provided as multiple stacked film layers, thereby improving the protective effect of the protective layer on the film layer structures in the display panel. For example, as shown in FIGS. 8A and 8B, the protective layer 500 further includes a second sub-protective layer 520. At least a portion of the second sub-protective layer 520 is located in the non-display region 11c. The second sub-protective layer 520 is located between the first sub-protective layer 510 and the substrate 100 in the non-display region 11c. The orthographic projection of the first planarization layer 121 on the substrate 100 is located within the orthographic projection of the first sub-protective layer 510 on the substrate 100 and within the orthographic projection of the second sub-protective layer 520 on the substrate 100 in the non-display region 11c. The second sub-protective layer 520 extends into the display region 11a. In the region where the first planarization layer 121 is provided, the first sub-protective layer 510 and the second sub-protective layer 520 are spaced apart by the first planarization layer 121, that is, the first planarization layer 121 is located between the first sub-protective layer 510 and the second sub-protective layer 520. In the above solution, the second sub-protective layer 520 can protect the underlying structures. Furthermore, the protective layer 500 is a structure including at least two film layers to further enhance the protective effect of the protective layer 500, thereby further improving the quality of the display panel.

In at least one embodiment of the present disclosure, as shown in FIGS. 8A and 8B, the orthographic projection of the pixel defining layer 330 on the substrate 100 is located within the orthographic projection of the second sub-protective layer 520 on the substrate 100. In this manner, the second sub-protective layer 520 covers the entire display region 11a to protect the structures below the pixel defining layer 330 in the display region 11a during the formation of the pixel defining layer 330.

In at least one embodiment of the present disclosure, as shown in FIGS. 8A and 8B, the display panel further includes a first signal line 131. The first signal line 131 is located on a side of the first planarization layer 121 facing the substrate 100. The presence of the first signal line 131 requires the setting of other film layers to space the first signal line 131 from the neighboring conductive structures, thereby providing an interlayer location for setting the second sub-protective layer 520.

In some embodiments of the present disclosure, the second sub-protective layer 520 may be located above the first signal line 131 to cover the first signal line 131. For example, as shown in FIGS. 8A and 8B, the second sub-protective layer 520 is located between the first signal line 131 and the first planarization layer 121. The first sub-protective layer 510 and the second sub-protective layer 520 are located between the first common electrode line 111 and the second common electrode line 112 in the non-display region 11c. In the above solution, the second sub-protective layer 520 can protect the first signal line 131 during the preparation of the first planarization layer 121 (for example, during the etching process required for opening holes). Furthermore, the second sub-protective layer 520 can prevent substances such as water and oxygen in the first planarization layer 121 from invading the first signal line 131, thereby reducing the risk of the first signal line 131 being corroded and damaged.

For example, as shown in FIGS. 8A and 8B, in the case where the second sub-protective layer 520 is located between the first signal line 131 and the first planarization layer 121, in the non-display region 11c, the first sub-protective layer 510 is provided with a first via 401, the first planarization layer 121 is provided with a second via 402 connected with the first via 401, and the second sub-protective layer 520 is provided with a third via 403 connected with the second via 402. The first common electrode line 111 is connected to the second common electrode line 112 through the first via 401, the second via 402, and the third via 403.

For example, as shown in FIGS. 8A and 8B, in the case where the second sub-protective layer 520 is located between the first signal line 131 and the first planarization layer 121, the second common electrode line 112 and the first signal line 131 are in the same layer and of the same material. In this manner, the first signal line 131 can be synchronously prepared during the preparation of the second common electrode line 112, thereby simplifying the preparation process of the display panel.

For example, as shown in FIGS. 8A and 8B, in the case where the second sub-protective layer 520 is located between the first signal line 131 and the first planarization layer 121, the first signal line 131 includes at least one of a power supply line or a data line.

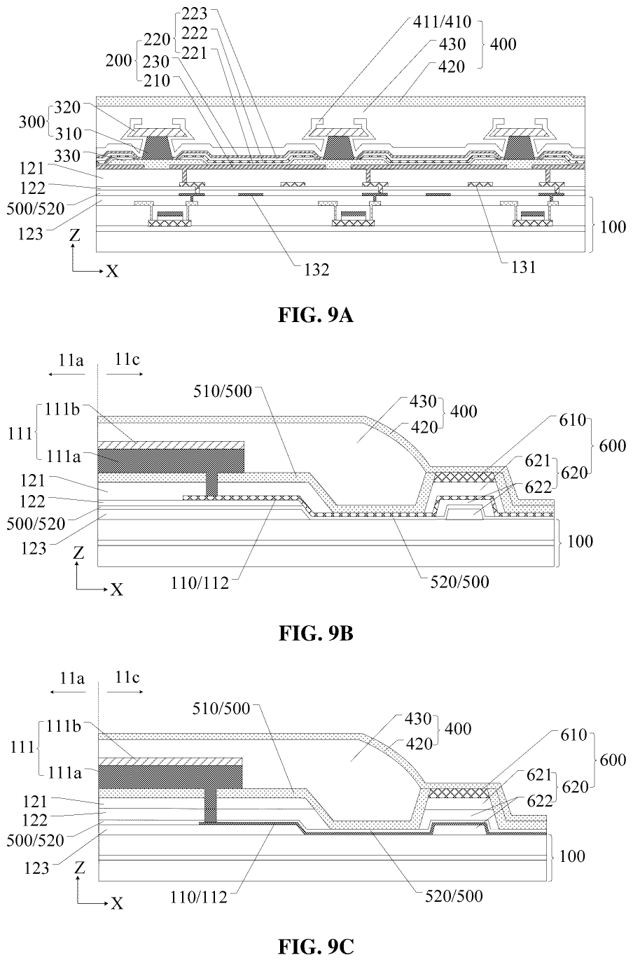

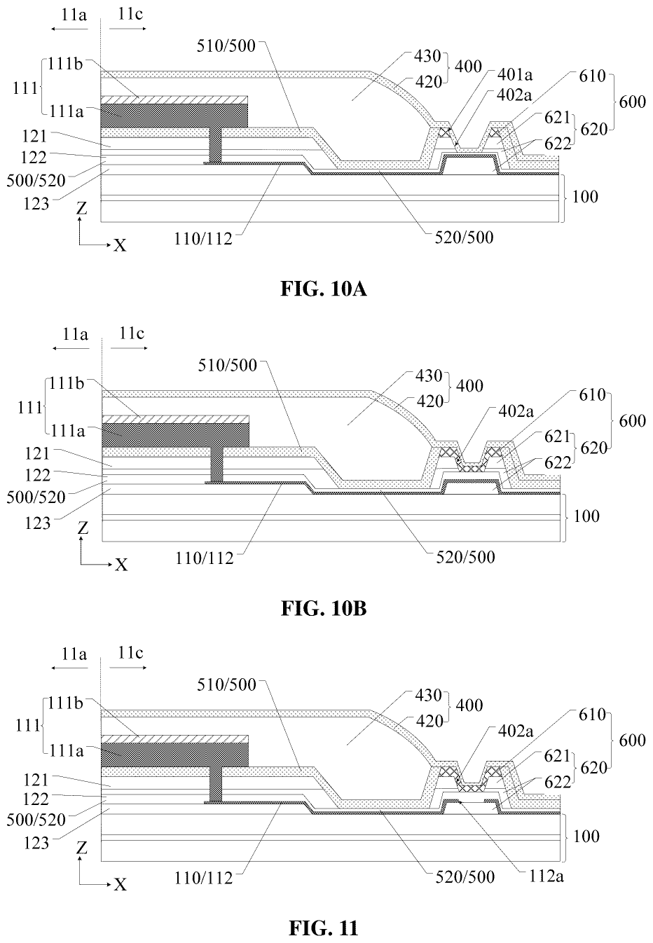

In other embodiments of the present disclosure, the second sub-protective layer 520 may be located below the first signal line 131. For example, as shown in FIGS. 9A and 9B, the display panel further includes a second signal line 132. The second signal line 132 and the second sub-protective layer 520 are located between the first signal line 131 and the substrate 100. When the first signal line 131 and the second signal line 132 are located in different layers, the wiring space of the display panel can be increased, thereby reducing the wiring difficulty. Accordingly, the number of film layers to be set can also be increased, thereby providing more options for the interlayer location of the second sub-protective layer 520.

For example, as shown in FIGS. 9A and 9B, the display panel further includes a second planarization layer 122 and a third planarization layer 123. The third planarization layer 123, the second signal line 132, the second planarization layer 122, the first signal line 131, and the first planarization layer 121 are sequentially arranged in the direction away from the substrate 100. The second sub-protective layer 520 is located between the second planarization layer 122 and the second signal line 132, specifically as shown in FIG. 9A, or the second sub-protective layer 520 is located between the second signal line 132 and the third planarization layer 123.

In at least one embodiment of the present disclosure, as shown in FIGS. 9A and 9B, at least a portion (for example, the support layer 620) of the bank 600 may be formed through at least two of the first planarization layer 121, the second planarization layer 122 or the third planarization layer 123 so that the second common electrode line 112 and the second sub-protective layer 520 may penetrate the interior of the bank 600. In this manner, at the location where the bank 600 is located, the height at which the second common electrode line 112 needs to be to cross the bank 600 can be reduced, thereby reducing the risk of breakage of the second common electrode line 112. Furthermore, at this location, the second common electrode line 112 is located inside the bank 600 to allow the bank 600 to protect the second common electrode line 112, thereby further reducing the risk of the second common electrode line 112 being damaged by etching.

In at least one embodiment of the present disclosure, as shown in FIGS. 9A and 9B, the bank 600 includes a top film layer 610 and a support layer 620. The portion where the second common electrode line 112 and the second sub-protective layer 520 penetrate the bank 600 is located inside the support layer 620.

For example, the support layer 620 includes a first sub-support layer 621 and a second sub-support layer 622. The first sub-support layer 621 and the first planarization layer 121 are in the same layer and of the same material. The second sub-support layer 622 and at least one of the second planarization layer 122 or the third planarization layer 123 are in the same layer and of the same material. In this manner, the portion where the second common electrode line 112 and the second sub-protective layer 520 penetrate the bank 600 is located between the first sub-support layer 621 and the second sub-support layer 622. Therefore, the setting of the support layer 620 does not increase the preparation process flow of the display panel.

In at least one embodiment of the present disclosure, as shown in FIGS. 9A and 9B, the second sub-protective layer 520 is located between the second signal line 132 and the second planarization layer 122. In this manner, the second sub-protective layer 520 can protect the second signal line 132 during the formation of the second planarization layer 122 (for example, during the formation of vias). Furthermore, the second sub-protective layer 520 can prevent substances such as water and oxygen in the second planarization layer 122 from invading the first signal line 131, thereby reducing the risk of the first signal line 131 being corroded and damaged.

For example, as shown in FIGS. 9A and 9B, in the case where the second sub-protective layer 520 is located between the second signal line 132 and the second planarization layer 122, the second common electrode line 112 and the second signal line 131 are in the same layer and of the same material so that the second sub-protective layer 520 is located between the second common electrode line 112 and the substrate 100. In this manner, the second sub-protective layer 520 can improve the surface properties of the substrate, thereby facilitating the deposition of the second common electrode line 112 and reducing the risk of the second common electrode line 112 being detached.

For example, as shown in FIGS. 9A and 9C, in the case where the second sub-protective layer 520 is located between the second signal line 132 and the second planarization layer 122, the second common electrode line 112 and the second signal line 132 are in the same layer and of the same material, and the second sub-protective layer 520 covers the second common electrode line 112. In this manner, the second common electrode line 112 can be synchronously prepared during the preparation of the second signal line 132, thereby simplifying the preparation process of the display panel.

In some embodiments of the present disclosure, as shown in FIG. 10A, in the case where the second sub-protective layer 520 is located between the second signal line 132 and the second planarization layer 122, the first sub-support layer 621 is provided with multiple second openings 402a. The second openings 402a are arranged at intervals along the bank 600. The second openings 402a expose the second sub-protective layer 520. The top film layer 610 includes first openings 401a each of which corresponds to a respective one of the second openings 402a. The second encapsulation layer 420 covers the second openings 402a and the first openings 401a and is in direct contact with the second sub-protective layer 520 through the second openings 402a and the first openings 401a. In this manner, the second openings 402a and the first openings 401a can release the gas enclosed inside the first sub-support layer 621, thereby ensuring the encapsulation effect of the display panel. Furthermore, the second encapsulation layer 420 covers and fills the second openings 402a and the first openings 401a to seal the second openings 402a and the first openings 401a, thereby preventing the gas from invading the bank 600 or the residual gas in the bank 600 from escaping during the subsequent preparation processes. In addition, with the setting of the second openings 402a and the first openings 401a, the second sub-protective layer 520 can be in direct contact with the second encapsulation layer 420, and the second encapsulation layer 420 is embedded in the bank 600 equivalently, thereby reducing the risk of the second encapsulation layer 420 being detached from the substrate 100.

In other embodiments of the present disclosure, as shown in FIG. 10B, the first sub-support layer 621 is provided with multiple second openings 402a. The second openings 402a are arranged at intervals along the bank 600. The second openings 402a expose the second sub-protective layer 520. The first sub-protective layer 510 covers the top film layer 610 and the second openings 402a to be in direct contact with the second sub-protective layer 520 through the second openings 402a. In this manner, the second openings 402a may be used for releasing the gas enclosed inside the first sub-support layer 621, thereby ensuring the encapsulation effect of the display panel. Furthermore, the first sub-protective layer 510 covers and fills the second openings 402a to seal the second openings 402a, thereby preventing the gas from invading the bank 600 or the residual gas in the bank 600 from escaping during the subsequent preparation process. In addition, with the setting of the second openings 402a, the first sub-protective layer 510 can be in direct contact with the second encapsulation layer 420, and the second encapsulation layer 420 is embedded in the bank 600 equivalently, thereby reducing the risk of the second encapsulation layer 420 being detached from the substrate 100.

In at least one embodiment of the present disclosure, as shown in FIG. 11, the second common electrode line 112 includes at least one air permeable hole 112a. The air permeable hole 112a penetrates the second common electrode line 112. The air permeable hole 112a may be used for releasing the gas enclosed inside the second sub-support layer 622, thereby ensuring the encapsulation effect of the display panel.

For example, as shown in FIG. 11, multiple air permeable holes 112a are provided and arranged at intervals along the bank 600. It is to be noted that the setting of the air permeable hole 112a does not disrupt the continuity of the second common electrode line 112. The structure shown in FIG. 11 is the section at the location where the air permeable hole 112a is located, and for the structure of the second common electrode line 112 at other locations, reference may be made to the structure shown in FIG. 10B.

It is to be noted that in the embodiments of the present disclosure, in the case where the second planarization layer 122 is provided and the third planarization layer 123 is not provided, the second planarization layer 122 is used for planarizing the driving circuit on the substrate; accordingly, in the case where the third planarization layer 123 is provided, the third planarization layer 123 is used for planarizing the driving circuit on the substrate.

In at least one embodiment of the present disclosure, with reference to FIG. 1, the non-display region 11c further includes a bending region 11d. The bank 600 is located between the bending region 11d and the display region 11a.

In at least one embodiment of the present disclosure, with reference to FIG. 1, the non-display region 11c may further include a binding region 11b. The binding region 11b may be provided with binding pins (which may be referred to as pads), and signal lines (for example, the common electrode line 110) in the display panel may be aggregated and then extend into the binding region 11b to be connected corresponding binding pins. For example, the common electrode line 110 extends from the display region 11a to the binding region 11b. The binding pins may be used for connecting to an external control circuit and/or a chip. For example, the binding region 11b is located on a side of the bending region 11d away from the display region 11a such that after the portion of the display panel in the bending region 11d is bent, the portion of the display panel in the binding region 11b and the structure connected to the binding region 11b are bent to the backside of the display panel, thereby narrowing the bezel width of the display panel.

In some scenarios, circuits are arranged in the portion, close to the display region, of the non-display region of the display panel, so the circuits are prone to be subjected to signal interference when the circuits are driven, thereby resulting in malfunctioning of the display panel. In the embodiments of the present disclosure, a signal shield structure may be provided in the portion to solve the above problem. The structure and principle of the signal shield structure will be described below.

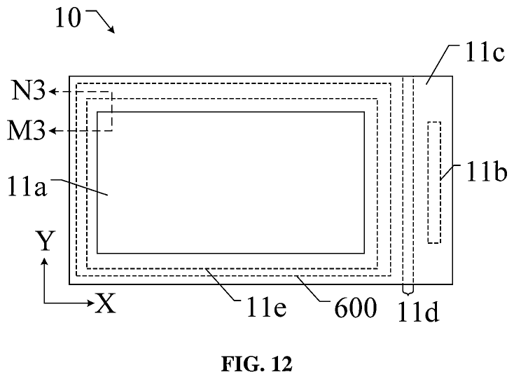

In at least one embodiment of the present disclosure, as shown in FIGS. 12 and 13A, the non-display region 11c includes a dummy sub-pixel region 11e, and the display panel further includes a second isolation structure 300a. The second isolation structure 300a is located in the dummy sub-pixel region 11e and on a side of the first sub-protective layer 510 away from the substrate 100. For example, the second isolation structure 300a is located between the bank 600 and the display region 11a. The second isolation structure 300a can protect the underlying structures, and in addition, the second isolation structure 300a can act as a signal shield to perform signal shielding on the underlying circuits (for example, a driving circuit or signal lines connected to the driving circuit), thereby preventing these circuits from interference from external signals (for example, signals generated by the touch structure 800 described below).

In some embodiments of the present disclosure, as shown in FIGS. 12 and 13A, the substrate 100 includes a gate driving circuit 130. The gate driving circuit 130 is located in the dummy sub-pixel region 11e. The orthographic projection of the gate driving circuit 130 on the substrate 100 at least partially overlaps the orthographic projection of the second isolation structure 300a on the substrate 100. For example, the orthographic projection of the gate driving circuit 130 on the substrate 100 is located within the orthographic projection of the second isolation structure 300a on the substrate 100. In this manner, the second isolation structure 300a can perform signal shielding on the gate driving circuit 130, thereby preventing the gate driving circuit 130 from interference from external signals.

In other embodiments of the present disclosure, as shown in FIGS. 12 and 13B, the substrate 100 includes a gate driving circuit 130. The gate driving circuit 130 is located on a side of the dummy sub-pixel region 11e away from the display region 11a. In this manner, the second isolation structure 300a can perform signal shielding on signal lines of the gate driving circuit, thereby preventing the signal lines from interference from external signals.

In other embodiments of the present disclosure, the orthographic projection of the gate driving circuit on the substrate 100 at least partially overlaps the orthographic projection of the first common electrode line 111 on the substrate 100. In this manner, the first common electrode line 111 can perform signal shielding on the gate driving circuit, thereby preventing the gate driving circuit from interference from external signals. For example, the orthographic projection of the gate driving circuit on the substrate 100 is located within the orthographic projection of the first common electrode line 111 on the substrate 100.

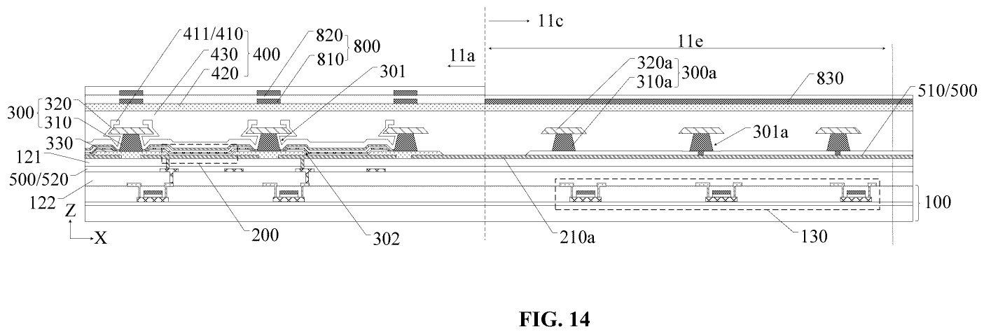

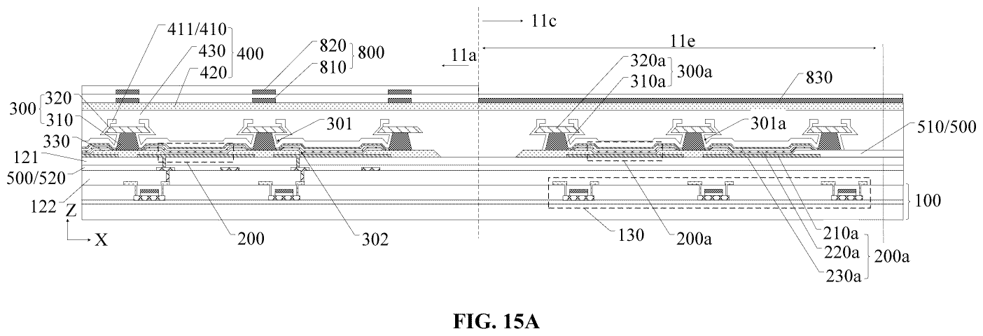

In at least one embodiment of the present disclosure, as shown in FIG. 14, the display panel further includes a touch structure 800. The touch structure 800 is located on a side of the second encapsulation layer 420 away from the substrate 100. The orthographic projection of a portion of the touch structure 800 on the substrate 100 overlaps the dummy sub-pixel region 11e.

Optionally, the touch structure 800 includes a touch electrode and a touch wire 830 connected to the touch electrode. The touch wire 830 extends from the display region 11a to the non-display region 11c. In this manner, the second isolation structure 300a and/or the first common electrode line 111 may shield the signals of the touch electrode or the touch wire 830, thereby preventing the gate driving circuit 130 in the lower layer or the signal lines connected to the gate driving circuit 130 from interference from these signals.

For example, the touch electrode includes a first touch electrode layer 810 and a second touch electrode layer 820. The first touch electrode layer 810 and the second touch electrode layer 820 constitute a touch unit for achieving a touch function. For example, one of the first touch electrode layer 810 and the second touch electrode layer 820 includes multiple first electrode strips disposed in parallel and multiple second electrode strips disposed in parallel. The first electrode strip intersects with the second electrode strip to form a touch unit at the intersection. The other one of the first touch electrode layer 810 and the second touch electrode layer 820 includes multiple conductive bridges. The first electrode strip is disconnected at the location where the first electrode strip intersects with the second electrode strip, that is, the first electrode strip is disconnected into multiple electrode blocks, and adjacent electrode blocks are electrically connected through a conductive bridge. It is to be noted that the first touch electrode layer 810 may also be set to include multiple first electrode strips, and the second touch electrode layer 820 may be set to include multiple second electrode strips so that the conductive bridges are not required.

In at least one embodiment of the present disclosure, the first electrode 830 may be of a single-layer design or may be of a double-layer design. For example, in the case of the single-layer design, the touch wire 830 and one of the first touch electrode layer 810 and the second touch electrode layer 820 may be in the same layer and of the same material. In the case of the double-layer design, one layer of the touch wire 830 and the first touch electrode layer 810 may be in the same layer and of the same material, and the other layer of the touch wire 830 and the second touch electrode layer 820 may be in the same layer and of the same material. In this manner, the touch wire 830 may be formed by the two layers of wires in parallel, thereby reducing the voltage drop generated on the touch wire 830.

In at least one embodiment of the present disclosure, as shown in FIG. 14, the second isolation structure 300a and the first isolation structure 300 may be synchronously prepared. For example, both the second isolation structure 300a and the first isolation structure 300 are prepared using a mask of the same format. In this manner, multiple second isolation openings 301a each of which corresponds to a respective one of the first isolation openings 301 are formed in the second isolation structure 300a. In the non-displayed region 11c, the second isolation openings 301a expose the first sub-protective layer 510 below the second isolation openings 301a.

It is to be noted that, since the dummy sub-pixel region 11e is not used for display, during the preparation of the light-emitting device 200, the second isolation opening 301a may be prepared using exactly the same preparation process flow as the first isolation opening 301 to prepare a light-emitting device (a dummy light-emitting device), or no light-emitting device may be prepared in this region. Different options will be described below.

In some embodiments of the present disclosure, no light-emitting device is prepared in the second isolation opening 301a. For example, as shown in FIG. 14, the display panel further includes a third encapsulation layer 430. The third encapsulation layer 430 is located between the first encapsulation layer 410 and the second encapsulation layer 420. The third encapsulation layer 430 fills the second isolation openings 301a and is in direct contact with the first sub-protective layer 510 in the second isolation openings 301a. In this manner, the first sub-protective layer 510 is a continuous film layer at the second isolation openings 301a, thereby protecting the underlying film layers during the formation of the second isolation openings 301a.

For example, as shown in FIG. 14, in the case where the third encapsulation layer 430 is in direct contact with the first sub-protective layer 510 in the second isolation openings 301a, the display panel further includes a dummy electrode 210a. The orthographic projection of the second isolation opening 301a on the substrate 100 is located within the orthographic projection of the dummy electrode 210a on the substrate 100. The dummy electrode 210a is used for shielding signals at the second isolation openings 301a, thereby avoiding signal interference between the touch structure 800 and the circuits on the substrate 100.

For example, as shown in FIG. 14, in the case where the third encapsulation layer 430 is in direct contact with the first sub-protective layer 510 in the second isolation openings 301a, the dummy electrode 210a is electrically connected to the second isolation structure 300a. In this manner, the dummy electrode 210a and the second isolation structure 300a may be equipotential, thereby eliminating the need to set a separate wire for the dummy electrode 210a.

For example, as shown in FIG. 14, in the case where the third encapsulation layer 430 is in direct contact with the first sub-protective layer 510 in the second isolation openings 301a, the dummy electrode 210a and the first electrode 210 are in the same layer and of the same material. The first sub-protective layer 510 is provided with a transfer hole. The dummy electrode 210a is connected to the second isolation structure 300a through the transfer hole. In this manner, the dummy electrode 210a can be synchronously prepared during the preparation of the first electrode 210, thereby simplifying the preparation process of the display panel.

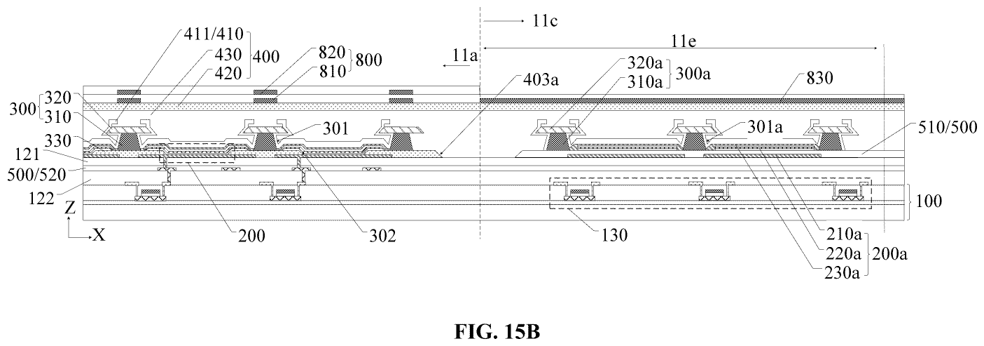

In other embodiments of the present disclosure, as shown in FIG. 15A, the display panel further includes a dummy light-emitting device 200a. The dummy light-emitting device 200a includes a first dummy electrode 210a, a first dummy light-emitting function layer 220a, and a second dummy electrode 230a which are sequentially stacked on the substrate 100. The first sub-protective layer 510 includes a dummy pixel opening 302 connecting with the second isolation opening 301a. The first dummy light-emitting function layer 220a and the second dummy electrode 230a are located in the dummy pixel opening 302 and the second isolation opening 301a, and the second dummy electrode 230a is connected to the second isolation structure 300a. In this manner, the dummy sub-pixel region 11e and the display region 11a are prepared using the same preparation process to form the dummy light-emitting device 200a corresponding to the light-emitting device 200 in the second isolation opening 301a. Therefore, the second dummy electrode 230a of the dummy light-emitting device 200a can be connected to the second isolation structure 300a, thereby achieving signal shielding.

In other embodiments of the present disclosure, as shown in FIGS. 15A and 15B, the display panel further includes a dummy light-emitting device 200a. The dummy light-emitting device 200a includes a first dummy electrode 210a, a first dummy light-emitting function layer 220a, and a second dummy electrode 230a which are sequentially stacked on the substrate 100. The first dummy electrode 210a is spaced apart from the first dummy light-emitting function layer 220a by the first sub-protective layer 510. The first dummy light-emitting function layer 220a and the second dummy electrode 230a are located in the second isolation opening 301a, and the second dummy electrode 230a is connected to the second isolation structure 300a. In the above solution, the dummy sub-pixel region 11e and the display region 11a are prepared using the same preparation process to form the dummy light-emitting device 200a corresponding to the light-emitting device 200 in the second isolation opening 301a. In this manner, the second dummy electrode 230a of the dummy light-emitting device 200a can be connected to the second isolation structure 300a, thereby achieving signal shielding. Furthermore, the first sub-protective layer 510 is a continuous film layer at the second isolation openings 301a, thereby protecting the underlying film layers during the formation of the second isolation openings 301a.

In at least one embodiment of the present disclosure, as shown in FIG. 15B, the first sub-protective layer 510 includes a third opening 403a to expose the first planarization layer 121 in the non-display region 11c. The orthographic projection of the third opening 403a on the substrate 100 is located between the orthographic projection of the first isolation structure 300 on the substrate 100 and the orthographic projection of the second isolation structure 300a on the substrate 100. In this manner, the third opening 403a may be used for releasing the gas enclosed inside the first planarization layer 121, thereby preventing the gas from adversely affecting the subsequent encapsulation.

It is to be noted that, taking FIG. 15B as an example, the first isolation structures 300 and the second isolation structures 300a are all grid-like structures, and the first common electrode line connected first isolation structures 300 and the first common electrode line connected second isolation structures 300a are connected to each other, respectively. FIG. 15B is a sectional view sectioned at the region where the isolation openings (which may be first isolation openings or second isolation openings) between the first isolation structures 300 and the second isolation structures 300a are located. In this manner, the first common electrode line is connected to the first isolation structure 300 through the second isolation structure 300a.

In at least one embodiment of the present disclosure, as shown in FIG. 15B, the first isolation structure 300 and the second isolation structure 300a are in the same layer and of the same material. In this manner, the second isolation structure 300a can be synchronously prepared during the preparation of the first isolation structure 300, thereby simplifying the preparation process of the display panel.

In at least one embodiment of the present disclosure, as shown in FIG. 15B, the second isolation structure 300a includes a second support portion 310a and a second crown portion 320a. The second support portion 310a is located between the second crown portion 320a and the substrate 100. The orthographic projection of the second crown portion 310a on the substrate 100 is located within the orthographic projection of the second crown portion 320a on the substrate 100. The first support portion 310 and the second support portion 310a are in the same layer and of the same material. The first crown portion 320 and the second crown portion 320a are in the same layer and of the same material.

In at least one embodiment of the present disclosure, the display panel further includes an optical adjustment structure (not shown) arranged on a side of the second encapsulation layer 420 away from the substrate 100, a polarization structure (not shown) arranged on a side of the touch structure 800 away from the substrate 100, and a cover plate (not shown).

At least one embodiment of the present disclosure provides a display panel. With reference to FIGS. 1, 2, 3A, and 3B, the display panel 10 has a display region 11a and a non-display region 11c and includes a substrate 100 and a bank 600, an encapsulation structure 400, a protective layer 500 and multiple light-emitting devices 200 which are located on the substrate 100. The light-emitting devices 200 are located in the display region 11a. The bank 600 is located in the non-display region 11c. The bank 600 includes a top film layer 610 away from the substrate 100. The encapsulation structure 400 is stacked on a side, away from the substrate 100, of the bank 600 and on a side, away from the substrate 100, of the light-emitting device 200. The protective layer 500 is at least partially located in the non-display region 11c. The protective layer 500 is located on a side, facing the substrate 100, of the encapsulation structure and laps the top film layer. The encapsulation structure 400 includes a first encapsulation layer 410 and a second encapsulation layer 420 which are stacked. The first encapsulation layer 410 is located on a side, facing the substrate 100, of the second encapsulation layer 420. The second encapsulation layer 420 extends from the display region 11a to the non-display region 11c and is in direct contact with the bank 600. In this manner, the protective layer 500 can protect underlying structures during the preparation process of the first encapsulation layer to avoid damage to the substrate 100 or the structures between the substrate 100 and the protective layer 500. Furthermore, the protective layer 500 can protect the side surface of the bank during the preparation of a pixel defining layer, thereby reducing the risk of the bank being damaged by etching. For the structure of the display panel, the problems to be solved, the corresponding effects, and the design structures to be further improved, reference may be made to the related descriptions in the above embodiments, and the details are not repeated here.

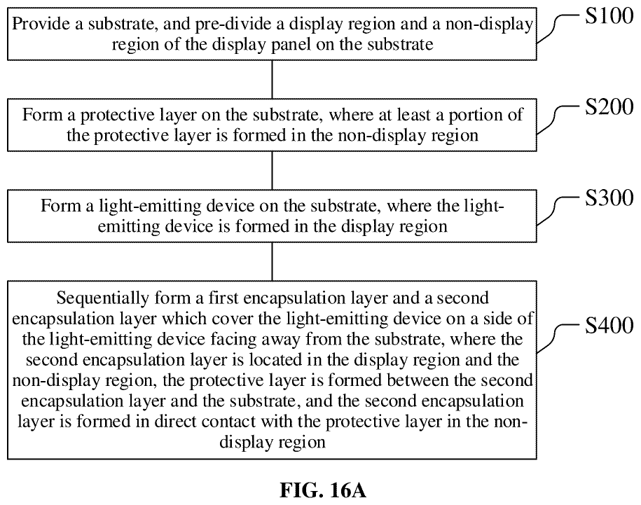

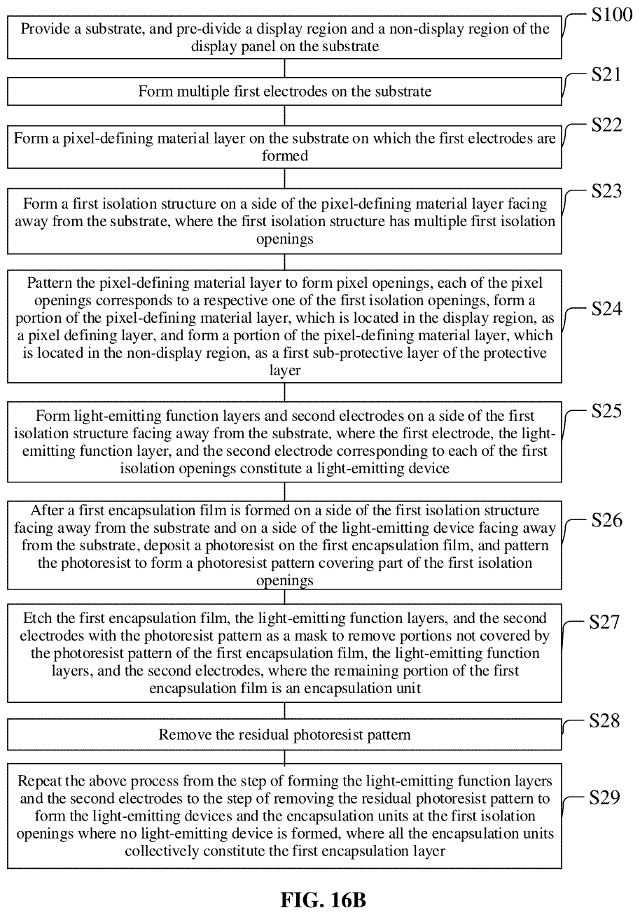

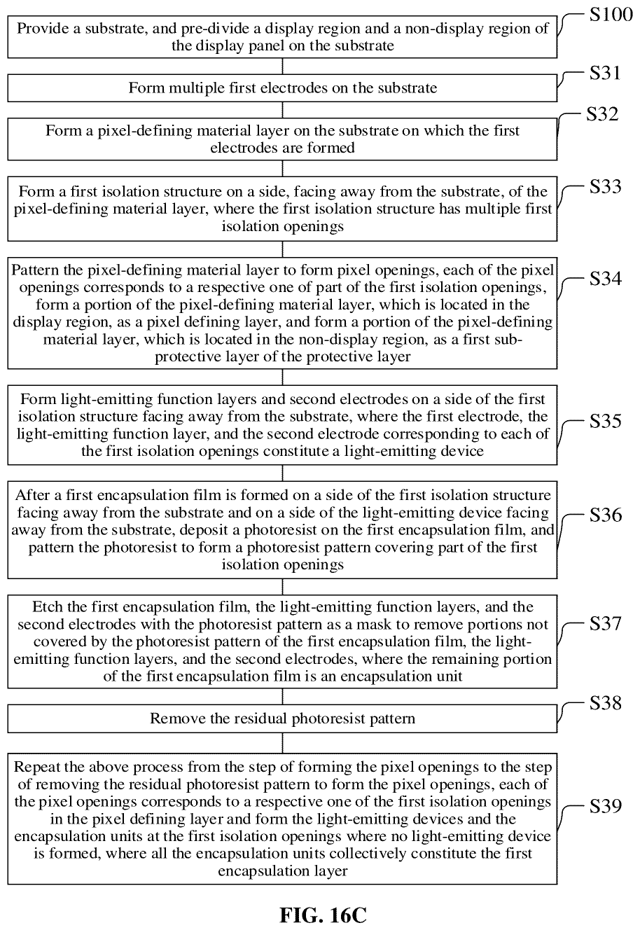

At least one embodiment of the present disclosure provides a method of preparing a display panel. As shown in FIG. 16A, the preparation method includes steps S100 to S300 described below.

In S100, a substrate is provided, and a display region and a non-display region of the display panel are pre-divided on the substrate.

In S200, a protective layer is formed on the substrate, where at least a portion of the protective layer is formed in the non-display region.

In S300, a light-emitting device is formed on the substrate, where the light-emitting device is formed in the display region.

In S400, a first encapsulation layer and a second encapsulation layer that cover the light-emitting device are sequentially formed on a side of the light-emitting device facing away from the substrate, where the second encapsulation layer is located in the display region and the non-display region, the protective layer is formed between the second encapsulation layer and the substrate, and the second encapsulation layer is formed in direct contact with the protective layer in the non-display region.

In the above preparation method, the protective layer can protect underlying structures during the preparation process of the first encapsulation layer to avoid damage to the substrate or the structures between the substrate and the protective layer, thereby ensuring the quality of the display panel. For the structure of the display panel obtained in steps S100 to S300, the problems to be solved, the corresponding effects, and the design structures to be further improved, reference may be made to the related descriptions in the above embodiments, and the details are not repeated here.

In the preparation method provided by the above embodiment, as shown in FIG. 16B, a method of forming the protective layer, the pixel defining layer, the light-emitting device, and the first encapsulation layer in steps S200 to S400 includes steps S21 to S29 described below. In S21, multiple first electrodes are formed on the substrate.

In S22, a pixel-defining material layer is formed on the substrate on which the first electrodes are formed.

In S23, a first isolation structure is formed on a side of the pixel-defining material layer facing away from the substrate, where the first isolation structure has multiple first isolation openings.

In S24, the pixel-defining material layer is patterned to form pixel openings, each of pixel openings corresponds to a respective one of the first isolation openings, a portion of the pixel-defining material layer, which is located in the display region, is formed as a pixel defining layer, and a portion of the pixel-defining material layer, which is located in the non-display region, is formed as a first sub-protective layer of the protective layer.

In S25, light-emitting function layers and second electrodes are formed on a side of the first isolation structure facing away from the substrate, where the first electrode, the light-emitting function layer, and the second electrode corresponding to each of the first isolation openings constitute a light-emitting device.

In S26, after a first encapsulation film is formed on a side of the first isolation structure facing away from the substrate and on a side of the light-emitting device facing away from the substrate, a photoresist is deposited on the first encapsulation film, and the photoresist is patterned to form a photoresist pattern covering part of the first isolation openings.

In S27, the first encapsulation film, the light-emitting function layers, and the second electrodes are etched with the photoresist pattern as a mask to remove portions not covered by the photoresist pattern of the first encapsulation film, the light-emitting function layers, and the second electrodes, where the remaining portion of the first encapsulation film is an encapsulation unit. In S28, the residual photoresist pattern is removed.

In S29, the above process from the step of forming the light-emitting function layers and the second electrodes to the step of removing the residual photoresist pattern is repeated to form the light-emitting devices and the encapsulation units at the first isolation openings where no light-emitting device is formed, where all the encapsulation units collectively constitute the first encapsulation layer.

For the structure of the display panel obtained in steps S21 to S29, the problems to be solved, the corresponding effects, and the design structures to be further improved, reference may be made to the related descriptions in the above embodiments, and the details are not repeated here.

In the preparation method provided by the above embodiments, as shown in FIG. 16C, another method of forming the protective layer, the pixel defining layer, the light-emitting device, and the first encapsulation layer in steps S200 to S400 includes steps S31 to S39 described below.

In S31, multiple first electrodes are formed on the substrate.

In S32, a pixel-defining material layer is formed on the substrate on which the first electrodes are formed.

In S33, a first isolation structure is formed on a side of the pixel-defining material layer facing away from the substrate, where the first isolation structure has multiple first isolation openings.

In S34, the pixel-defining material layer is patterned to form pixel openings, each of the pixel openings corresponds to a respective one of part of the first isolation openings, a portion of the pixel-defining material layer, which is located in the display region, is formed as a pixel defining layer, and a portion of the pixel-defining material layer, which is located in the non-display region, is formed as a first sub-protective layer of the protective layer.

In S35, light-emitting function layers and second electrodes are formed on a side, facing away from the substrate, of the first isolation structure, where the first electrode, the light-emitting function layer, and the second electrode corresponding to each of the first isolation openings constitute a light-emitting device.

In S36, after a first encapsulation film is formed on a side of the first isolation structure facing away from the substrate and on a side of the light-emitting device facing away from the substrate, a photoresist is deposited on the first encapsulation film, and the photoresist is patterned to form a photoresist pattern covering part of the first isolation openings.

In S37, the first encapsulation film, the light-emitting function layers, and the second electrodes are etched with the photoresist pattern as a mask to remove portions not covered by the photoresist pattern of the first encapsulation film, the light-emitting function layers, and the second electrodes, where the remaining portion of the first encapsulation film is an encapsulation unit.

In S38, the residual photoresist pattern is removed.

In S39, the above process from the step of forming the pixel openings to the step of removing the residual photoresist pattern is repeated to form the pixel openings each of which corresponds to a respective one of the first isolation openings in the pixel defining layer and form the light-emitting devices and the encapsulation units at the first isolation openings where no light-emitting device is formed, where all the encapsulation units collectively constitute the first encapsulation layer.

The process of preparing the display panel shown in FIG. 3A is described in conjunction with FIGS. 17A to 17I to visually illustrate the principle behind why the first isolation structure can increase the PPI.

As shown in FIG. 17A, a substrate 100 is provided, and first electrodes 210 arranged in an array are formed on the substrate 100.

As shown in FIG. 17B, a pixel-defining material layer 330a is deposited on the substrate 100 on which the first electrodes 210 are formed. In the above process, a variation in the density of the pixel-defining material layer 330a during formation may be regulated by controlling the input power of equipment during the deposition of the pixel-defining material layer 330a.

As shown in FIG. 17C, a first material layer 310b and a second material layer 320b are formed on the pixel-defining material layer 330a. For example, the material of the first material layer 310b may be aluminum, and the material of the second material layer 320b may be titanium.

As shown in FIG. 17D, the first material layer 310b and the second material layer 320b are patterned so that the first material layer 310b is formed as a first support portion 310 and the second material layer 320b is formed as a first crown portion 320. The first support portion 310 and the first crown portion 320 define a first isolation opening 301, and the first support portion 310 and the first crown portion 320 form a first isolation structure 300. For the specific structure of the first isolation structure 300, reference may be made to the related descriptions in the above embodiments, and the details are not repeated here.

In the embodiments of the present disclosure, the patterning process may be photolithographic patterning and may include, for example, the following steps. A photoresist is coated on a structure layer to be patterned, the photoresist is exposed using a mask, the exposed photoresist is developed to obtain a photoresist pattern, the structure layer is etched (optionally by wet etching or dry etching) using the photoresist pattern, and then the photoresist pattern is optionally removed. It is noted that in the case where the material of the structure layer (for example, the photoresist pattern 900 described below) is a photoresist, the structure layer may be exposed directly through a mask to form the desired pattern.

It is to be noted that if the corrosion resistance of the second material layer 320b (for example, titanium) is greater than the corrosion resistance of the first material layer 310b (for example, aluminum), the etching rate of the first material layer 310b is faster than the etching rate of the second material layer 320b, and thus, the width of the first crown portion 320 is greater than the width of the first support portion 310 to form the structure shown in FIG. 17D.

As shown in FIG. 17E, the pixel-defining material layer 330a is patterned to form pixel openings 302 at part of the first isolation openings 301, a portion of the pixel-defining material layer 330a, which is located in the display region, is formed as a pixel defining layer 330 (not in its final form), and a portion of the pixel-defining material layer 330a, which is located in the non-display region, is formed as a first sub-protective layer.

It is to be noted that, in the step shown in FIG. 17E, the pixel openings 302 may be formed by photolithographic patterning. In the process of photolithographic patterning, the photoresist may also be exposed using the first isolation structure 300, thereby accurately controlling the locations where the pixel openings 302 are formed.

During the above preparation of the first isolation structure, at least a portion of the first material layer 310b and at least a portion of the second material layer 320b in the non-display region need to be removed, and if no protective layer (the first sub-protective layer) exists in the non-display region, the etching material in the process will etch and damage the structure on the substrate.

As shown in FIG. 17F, the light-emitting function layers 220 and the second electrodes 230 are vapor-deposited on the substrate 100 to form a light-emitting device 200 in each isolation opening 301 of the first isolation structure 300. Since no mask is used during the vapor deposition in the above process, the vapor-deposited material will also be deposited on the first crown portion 320. It is to be noted that, in the actual process, the vapor-deposited material will be deposited on the upper surface, facing away from the substrate 100, of the first crown portion 320 as well as at the sidewalls of the first crown portion 320 (not shown); then the first encapsulation film 410a is deposited to cover the light-emitting device 200 and the first isolation structure 300. In the above process, a variation in the density of the first encapsulation film 410a during formation may be regulated by controlling the input power of equipment during the deposition of the first encapsulation film 410a.

It is to be noted that since the light-emitting function layer 220 and the first electrode 210 are spaced apart from each other at a location where the first isolation opening 301 is formed but the pixel opening 302 is not formed, the light-emitting function layer 220 and the first electrode 210 of the light-emitting device 200 at this location are separated from each other, and thus the light-emitting device 20 does not have a light-emitting function.

As shown in FIG. 17G, a photoresist is formed (for example, by coating) on the substrate 100 on which the first encapsulation film 410a is formed and patterned to form a photoresist pattern 900. The photoresist pattern 900 covers only part of the first isolation openings 301 (first isolation openings 301 corresponding to the pixel openings 302) of the first isolation structure 300.

As shown in FIG. 17H, the surface of the display panel is etched with the photoresist pattern 900 as a mask, the first encapsulation film 410a, the second electrodes 230, and the light-emitting function layers 220 which are not covered by the photoresist pattern 900 are removed, and the remaining portion of the first encapsulation film 410a forms an encapsulation unit 411 of the first encapsulation layer 410; then the residual photoresist pattern 900 is removed. If no protective layer (the first sub-protective layer) exists in the non-display region, the etching process will etch and damage the structure on the substrate.

As shown in FIG. 17I, the pixel defining layer 330 is patterned to form pixel openings 302 at locations where another part of the first isolation openings 301 are located (where no pixel openings 302 were formed before).

The steps shown in FIGS. 17E to 17H are repeated to form the light-emitting devices 200 emitting green light and the light-emitting devices 200 emitting blue light in the other first isolation openings 301, respectively, thereby forming the display panel shown in FIG. 3A.

As shown in FIG. 18, when the light-emitting function layer (for example, the first function layer therein) is to be vapor-deposited, if the vapor deposition source P is moved to a location directly facing the first isolation structure 300, the locations corresponding to the boundaries of the vapor deposition angle of the vapor deposition source P on the display panel are the line L1 and the line L2, that is, the regions in front of the line L1 and the line L2 are not vapor-deposited while the regions on the sides, away from the first isolation structure 300, of the line L1 and the line L2 are vapor-deposited regardless of the location to which the vapor deposition source P is moved. That is, starting from the region of the line L1 or the line L2, the closer the light-emitting function layer is to the first isolation structure 300, the smaller the thickness of the light-emitting function layer is. Similarly, the second electrode may be formed based on the vapor deposition, and thus, the closer the second electrode is to the first isolation structure 300, the smaller the thickness of the second electrode is.

At least one embodiment of the present disclosure provides a display device. The display device includes a display panel mentioned in any of the above embodiments or a display panel prepared by the preparation method mentioned in any of the above embodiments. For example, the display device may be any product or component having a display function, such as a television, a digital camera, a mobile phone, a watch, a tablet computer, a laptop computer, and a navigator.

The above are only preferred embodiments of the present disclosure and are not intended to limit the present disclosure. Any modifications, equivalent substitutions, and the like within the spirit and principle of the present disclosure are within the scope of the present disclosure.

What is claimed is:

1. A display panel having a display region and a non-display region, comprising:
a substrate;
a plurality of light-emitting devices located on a side of the substrate and located in the display region;
an encapsulation structure located on a side of the plurality of light-emitting devices away from the substrate, and the encapsulation structure comprising a first encapsulation layer and a second encapsulation layer located on a side of the first encapsulation layer facing away from the substrate, the first encapsulation layer and the second encapsulation layer covering the plurality of light-emitting devices, and an orthographic projection of the second encapsulation layer on the substrate being located in the display region and the non-display region; and
a protective layer at least partially located in the non-display region and located on a side of the second encapsulation layer facing the substrate, wherein the protective layer is in direct contact with the second encapsulation layer in the non-display region, and the protective layer and the second encapsulation layer are of a same material.

2. The display panel according to claim 1, further comprising a pixel defining layer located on the substrate, wherein the pixel defining layer is located in the display region and is provided with a plurality of pixel openings, the plurality of pixel openings are used for accommodating the plurality of light-emitting devices, the protective layer comprises a first sub-protective layer, the first sub-protective layer laps the pixel defining layer, and the first sub-protective layer and the second encapsulation layer are in direct contact in the non-display region; and
the pixel defining layer, the first encapsulation layer, the second encapsulation layer, and the protective layer are inorganic film layers.

3. The display panel according to claim 2, wherein the first sub-protective layer and the pixel defining layer are disposed in a same layer and of a same material.

4. The display panel according to claim 2, wherein an orthographic projection of the first sub-protective layer on the substrate is located in the display region and the non-display region, the first sub-protective layer at least partially overlaps the pixel defining layer in the display region, and the first sub-protective layer is located between the pixel defining layer and the substrate.

5. The display panel according to claim 4, wherein each of the light-emitting devices comprises a first electrode, a light-emitting function layer, and a second electrode which are sequentially stacked on the substrate in a direction away from the substrate, and the first sub-protective layer is located between the first electrode and the substrate.

6. The display panel according to claim 5, further comprising a first planarization layer located between the substrate and the first electrode, wherein
the first planarization layer is located in the display region and the non-display region, the first planarization layer is in contact with the first sub-protective layer in the non-display region, and the first sub-protective layer is located between the first electrode and the first planarization layer in the display region.

7. The display panel according to claim 2, wherein an orthographic projection of the first sub-protective layer on the substrate is located in the display region and the non-display region, the first sub-protective layer at least partially overlaps the pixel defining layer in the display region, and the pixel defining layer is located between the first sub-protective layer and the substrate.

8. The display panel according to claim 7, wherein each of the light-emitting devices comprises a first electrode, a light-emitting function layer, and a second electrode which are sequentially stacked on the substrate in a direction away from the substrate, and
the orthographic projection of the first sub-protective layer on the substrate is located outside an orthographic projection of the first electrode on the substrate.

9. The display panel according to claim 8, further comprising a first planarization layer between the substrate and the first electrode, wherein the first planarization layer is located in the display region and the non-display region, and the first planarization layer is in contact with the first sub-protective layer in the non-display region.

10. The display panel according to claim 2, further comprising at least one bank located in the non-display region, wherein a bank of the at least one bank surrounds at least a portion of the display region, the bank comprises a top film layer on a side away from the substrate, the first sub-protective layer is in contact with the top film layer, and the first sub-protective layer and the top film layer are of a same material.

11. The display panel according to claim 10, wherein
the first sub-protective layer and the top film layer are arranged in a same layer, and the first sub-protective layer covers a side surface of the bank; or
the first sub-protective layer covers the top film layer, the first sub-protective layer is located on a side of the top film layer facing away from the substrate, and an orthographic projection of the top film layer on the substrate is located within an orthographic projection of the first sub-protective layer on the substrate.

12. The display panel according to claim 11, wherein the top film layer comprises a plurality of first openings, the orthographic projection of the first sub-protective layer on the substrate is located outside orthographic projections of the plurality of first openings on the substrate, and the orthographic projections of the plurality of first openings on the substrate are located within the orthographic projection of the second encapsulation layer on the substrate; and
the second encapsulation layer covers and fills the first opening.

13. The display panel according to claim 10, wherein the bank comprises a support layer, the support layer is located between the top film layer and the substrate, and the first sub-protective layer covers a side surface of the support layer.

14. The display panel according to claim 13, further comprising a first planarization layer, wherein the first planarization layer is spaced apart from the bank, the first planarization layer is located in the display region and the non-display region, the first planarization layer is located between the pixel defining layer and the substrate and between the first sub-protective layer and the substrate, at least a portion of the support layer and the first planarization layer are disposed in a same layer, and are of a same material.

15. The display panel according to claim 10, further comprising a third encapsulation layer, wherein the third encapsulation layer is located between the first encapsulation layer and the second encapsulation layer, and the third encapsulation layer is located on a side of the bank facing the display region; and
the first sub-protective layer is in direct contact with the third encapsulation layer between the bank and the display region.

16. The display panel according to claim 2, wherein the protective layer further comprises a second sub-protective layer, at least a portion of the second sub-protective layer is located in the non-display region, and the second sub-protective layer is located between the first sub-protective layer and the substrate in the non-display region.

17. The display panel according to claim 16, further comprising a first planarization layer and a first signal line, wherein the first planarization layer is located in the display region and the non-display region, the first planarization layer is located between the pixel defining layer and the substrate and between the first sub-protective layer and the substrate,
in the non-display region, an orthographic projection of the first planarization layer on the substrate is located within an orthographic projection of the first sub-protective layer on the substrate, and within an orthographic projection of the second sub-protective layer on the substrate, and the first signal line is located on a side of the first planarization layer facing the substrate.

18. The display panel according to claim 17, wherein the second sub-protective layer is located between the first signal line and the first planarization layer, each of the light-emitting devices comprises a first electrode, a light-emitting function layer, and a second electrode which are sequentially stacked on the substrate in a direction away from the substrate, and the first sub-protective layer is located between the first electrode and the substrate;
the display panel further comprises a first common electrode line and a second common electrode line, the first common electrode line is located in the display region and the non-display region, the second common electrode line is located in the non-display region, the first common electrode line is located on a side of the first sub-protective layer facing away from the substrate and on a side of the pixel defining layer facing away from the substrate, the second common electrode line is located between the first sub-protective layer and the substrate, and the first common electrode line is electrically connected to the second electrode; and
in the non-display region, the first sub-protective layer and the second sub-protective layer are located between the first common electrode line and the second common electrode line.

19. The display panel according to claim 17, further comprising a second signal line, wherein the second signal line and the second sub-protective layer are located between the first signal line and the substrate.

20. The display panel according to claim 19, further comprising a second planarization layer and a third planarization layer, wherein the third planarization layer, the second signal line, the second planarization layer, the first signal line, and the first planarization layer are sequentially arranged in a direction away from the substrate; and
the second sub-protective layer is located between the second planarization layer and the second signal line, or the second sub-protective layer is located between the second signal line and the third planarization layer.

21. The display panel according to claim 20, wherein each of the light-emitting devices comprises a first electrode, a light-emitting function layer, and a second electrode which are sequentially stacked on the substrate in the direction away from the substrate, and the first sub-protective layer is located between the first electrode and the substrate;
the display panel further comprises a first common electrode line and a second common electrode line, the first common electrode line is located in the display region and the non-display region, the second common electrode line is located in the non-display region, the first common electrode line is located on a side of the first sub-protective layer facing away from the substrate and on a side of the pixel defining layer facing away from the substrate, the second common electrode line is located between the first sub-protective layer and the substrate, and the first common electrode line is electrically connected to the second electrode; and
the display panel further comprises at least one bank located in the non-display region, a bank of the at least one bank surrounds the display region, and the second common electrode line and the second sub-protective layer penetrate an interior of the bank.

22. The display panel according to claim 21, wherein the bank comprises a top film layer and a support layer, and the support layer is located between the top film layer and the substrate; and
the support layer comprises a first sub-support layer and a second sub-support layer which are stacked on one another, the second sub-support layer is located between the first sub-support layer and the substrate, the first sub-support layer and the first planarization layer are disposed in a same layer and of a same material, the second sub-support layer and at least one of the second planarization layer or the third planarization layer are disposed in a same layer and of a same material, and a portion where the second common electrode line and the second sub-protective layer penetrate the bank is located between the first sub-support layer and the second sub-support layer.

23. The display panel according to claim 2, further comprising a first isolation structure located on a side of the pixel defining layer away from the substrate, wherein the first isolation structure is located in the display region and is provided with a plurality of first isolation openings, a first isolation opening of the plurality of first isolation openings communicates with a corresponding pixel opening, the first encapsulation layer comprises a plurality of encapsulation units, and the plurality of encapsulation units are located on a side of the plurality of light-emitting devices facing away from the substrate to encapsulate the plurality of light-emitting devices; and
each of the light-emitting devices comprises a first electrode, a light-emitting function layer, and a second electrode which are sequentially stacked on the substrate in a direction away from the substrate, the light-emitting function layer and the second electrode are located within the first isolation opening, and the second electrode is electrically connected to the first isolation structure.

24. The display panel according to claim 23, wherein the non-display region comprises a dummy sub-pixel region, the display panel further comprises a second isolation structure, and the second isolation structure is located in the dummy sub-pixel region and on a side of the first sub-protective layer away from the substrate.

25. The display panel according to claim 24, wherein
the substrate comprises a gate driving circuit, the gate driving circuit is located in the dummy sub-pixel region, and an orthographic projection of the gate driving circuit on the substrate at least partially overlaps an orthographic projection of the second isolation structure on the substrate; or
the substrate comprises a gate driving circuit, and the gate driving circuit is located on a side of the dummy sub-pixel region away from the display region.

26. The display panel according to claim 25, further comprising a touch structure, wherein the touch structure is located on a side, away from the substrate, of the second encapsulation layer, and an orthographic projection of the touch structure on the substrate partially overlaps the dummy sub-pixel region.

27. The display panel according to claim 24, wherein the first sub-protective layer comprises a third opening to expose a first planarization layer in the non-display region, and an orthographic projection of the third opening on the substrate is located between an orthographic projection of the first isolation structure on the substrate and an orthographic projection of the second isolation structure on the substrate.

28. The display panel according to claim 24, wherein the first isolation structure and the second isolation structure are disposed in a same layer and of a same material;
the first isolation structure comprises a first support portion and a first crown portion, the first support portion is located between the first crown portion and the substrate, and an orthographic projection of the first support portion on the substrate is located within an orthographic projection of the first crown portion on the substrate; and
the second isolation structure comprises a second support portion and a second crown portion, the second support portion is located between the second crown portion and the substrate, an orthographic projection of the second crown portion on the substrate is located within an orthographic projection of the second crown portion on the substrate, the first support portion and the second support portion are disposed in a same layer and of a same material, and the first crown portion and the second crown portion are disposed in a same layer and of a same material.

29. A display panel having a display region and a non-display region, comprising:
a substrate;
a plurality of light-emitting devices located on the substrate and located in the display region;
a bank located on the substrate and located in the non-display region, the bank comprising a top film layer away from the substrate;
an encapsulation structure stacked on a side of the bank away from the substrate and on a side of the light-emitting device away from the substrate; and
a protective layer at least partially located in the non-display region, wherein the protective layer is located on a side of the encapsulation structure facing the substrate and laps the top film layer;
wherein the encapsulation structure comprises a first encapsulation layer and a second encapsulation layer which are stacked, the first encapsulation layer is located on a side of the second encapsulation layer facing the substrate, and the second encapsulation layer is located in the display region and the non-display region and is in direct contact with the bank.

30. A method of preparing a display panel, comprising:
providing a substrate, and pre-dividing a display region and a non-display region of the display panel on the substrate;
forming a protective layer on the substrate, wherein at least a portion of the protective layer is formed in the non-display region;
forming a light-emitting device on the substrate, wherein the light-emitting device is formed in the display region; and
sequentially forming a first encapsulation layer and a second encapsulation layer which cover the light-emitting device on a side of the light-emitting device facing away from the substrate, wherein the second encapsulation layer is located in the display region and the non-display region, the protective layer is formed between the second encapsulation layer and the substrate, and the second encapsulation layer is formed in direct contact with the protective layer in the non-display region.
